(19) United States
(12) Patent Application Publication
(10) Pub. No.: US 2024/0085246 A1
(43) Pub. Date: Mar. 14, 2024

(54) MEASUREMENT CIRCUIT AND ELECTRONIC EQUIPMENT

(71) Applicant: SONY SEMICONDUCTOR SOLUTIONS CORPORATION, KANAGAWA (JP)

(72) Inventors: TAKURO KOSAKA, KANAGAWA (JP); KYOICHI TAKENAKA, KANAGAWA (JP)

(21) Appl. No.: 17/754,688

(22) PCT Filed: Jul. 13, 2020
(86) PCT No.: PCT/JP2020/027194

§ 371 Date: Apr. 8, 2022

(30) Foreign Application Priority Data
Oct. 18, 2019 (JP) 2019-190630

(51) Int. Cl. G01K 7/00; G01R 19/00; G01R 19/10

(52) U.S. Cl. CPC G01K 7/00; G01R 19/0023; G01R 19/10

(57) ABSTRACT

To improve the temperature measurement accuracy in a circuit that measures temperature by using an operational amplifier.

An operational amplifier outputs an output voltage corresponding to a difference between terminal voltages of a pair of input terminals. A resistor has one end connected to one of the pair of input terminals. A resistor-side rectification element is connected to another end of the resistor. A terminal-side rectification element is connected to the other one of the pair of input terminals. A switch connects an additional rectification element in parallel with either the resistor-side rectification element or the terminal-side rectification element. A current output section outputs a current corresponding to the output voltage. A difference acquisition section acquires, as temperature data, a difference between a signal corresponding to the current provided when the additional rectification element is not connected to the resistor-side rectification element or the terminal-side rectification element and a signal corresponding to the current provided when the additional rectification element is connected to the resistor-side rectification element or the terminal-side rectification element.

### TECHNICAL FIELD

The present technology relates to a measurement circuit and electronic equipment. Specifically, the present technology relates to a temperature sensor and electronic equipment that generate a signal corresponding to temperature.

### BACKGROUND ART

In the known art, in-vehicle equipment and the like are often provided with a function of measuring temperature during operation in order to controllably prevent degradation of performance of the equipment in spite of an increase in temperature. For example, there has been proposed an imaging apparatus that is provided with a BGR (Band Gap Reference) circuit for measuring temperature during capturing of image data (see, for example, PTL 1). A resistor, an operational amplifier, and a transistor are disposed in the BGR circuit, and the transistor outputs a current that is proportional to the temperature. The temperature measured from the current is used to correct a pixel signal. A dark current component in the pixel signal fluctuates according to the temperature, and thus, for example, the dark current component is corrected on the basis of the temperature.

### CITATION LIST

### Patent Literature

### [PTL 1]

JP 2011-188224A

### SUMMARY

### Technical Problems

In the related art described above, the measured temperature is used to correct the pixel signal, improving image quality. However, in the above-described circuit, there is a possibility that the measured value of the temperature may have an error due to an input offset voltage of the operational amplifier in the BGR circuit. The error in the measured value of the temperature prevents the pixel signal from being appropriately corrected, resulting in degraded image quality.

The present technology has been developed in view of these circumstances, and an object of the present technology is to provide a circuit that measures temperature by using an operational amplifier, with an improved temperature measurement accuracy.

### Solution to Problems

The present technology has been made to solve the problems described above. According to a first aspect of the present technology, there is provided a measurement circuit that includes an operational amplifier configured to output an output voltage corresponding to a difference between terminal voltages of a pair of input terminals, a resistor having one end connected to one of the pair of input terminals, a resistor-side rectification element connected to the other end of the resistor, a terminal-side rectification element connected to the other one of the pair of input terminals, an additional rectification element, a switch configured to connect the additional rectification element in parallel with either the resistor-side rectification element or the terminal-side rectification element, a current output section configured to output a current corresponding to the output voltage, and a difference acquisition section configured to acquire, as temperature data, a difference between a signal corresponding to the current provided when the additional rectification element is not connected to the resistor-side rectification element or the terminal-side rectification element and a signal corresponding to the current provided when the additional rectification element is connected to the resistor-side rectification element or the terminal-side rectification element. This produces an effect of eliminating components of an input offset voltage of the operational amplifier.

Additionally, in the first aspect, the measurement circuit may further include a current-to-voltage conversion section configured to convert the current into a voltage, and the difference acquisition section may acquire a difference in the voltage as the temperature data. This produces an effect of acquiring the difference in voltage as the temperature data.

Additionally, in the first aspect, the current output section may include a current mirror circuit configured to output, to the current-to-voltage conversion section, a current supplied from an input node, a first P-type transistor that is interposed between a power supply and the terminal-side rectification element and that has a gate to which the output voltage is input, a second P-type transistor that is interposed between the power supply and the resistor and that has a gate to which the output voltage is input, and a third P-type transistor that is interposed between the power supply and the input node and that has a gate to which the output voltage is input. This has an effect of outputting a current via the current mirror circuit.

Additionally, in the first aspect, the current output section may include a first P-type transistor that is interposed between a power supply and the terminal-side rectification element and that has a gate to which the output voltage is input and a second P-type transistor that is interposed between the power supply and the resistor and that has a gate to which the output voltage is input. The terminal-side rectification element and the resistor-side rectification element may be connected to the current-to-voltage conversion section via a predetermined common node and share a common connection. This produces an effect of omitting the current mirror circuit.

Additionally, in the first aspect, the current generation section may include a first P-type transistor that is interposed between a power supply and the terminal-side rectification element and that has a gate to which the output voltage is input, a second P-type transistor that is interposed between the power supply and the resistor and that has a gate to which the output voltage is input, and a third P-type transistor that is interposed between the power supply and the current-to-voltage conversion section and that has a gate to which the output voltage is input. This produces an effect of omitting the current mirror circuit.

Additionally, in the first aspect, the measurement circuit can further include a voltage buffer configured to output a voltage of a node between the resistor and the current output section. This produces an effect of omitting the current-to-voltage conversion section.

Additionally, in the first aspect, the additional rectification element may include a first additional rectification element and a second additional rectification element, the switch may include a first switch and a second switch, the first switch may connect the first additional rectification element in parallel with one of the resistor-side rectification element and the terminal-side rectification element, and the second switch may connect the second additional rectification element in parallel with the other one of the resistor-side rectification element and the terminal-side rectification element. This produces an effect of facilitating fine-tuning of coefficients with respect to temperature.

Additionally, in the first aspect, the terminal-side rectification element, the resistor-side rectification element, and the additional rectification element may be diode-connected transistors. This produces an effect of generating temperature data on the basis of the temperature characteristics of the transistors.

Additionally, in the first aspect, the terminal-side rectification element, the resistor-side rectification element, and the additional rectification element may be diodes. This produces an effect of generating temperature data on the basis of the temperature characteristics of the diodes.

In addition, in the first aspect, the measurement circuit may further include a dummy switch that is in an on-state and that is disposed at each position between the resistor-side rectification element and a predetermined common node and between the terminal-side rectification element and the predetermined common node. The switch and the dummy switch may be transistors having an identical polarity. This produces an effect of making the common node-side potentials of the rectification elements equal.

Additionally, according to a second aspect of the present technology, there is provided electronic equipment that includes an operational amplifier configured to output an output voltage corresponding to a difference between terminal voltages of a pair of input terminals, a resistor having one end connected to one of the pair of input terminals, a resistor-side rectification element connected to the other end of the resistor, a terminal-side rectification element connected to the other one of the pair of input terminals, an additional rectification element, a switch configured to connect the additional rectification element in parallel with either the resistor-side rectification element or the terminal-side rectification element, a current output section configured to output a current corresponding to the output voltage, a difference acquisition section configured to acquire, as temperature data, a difference between a signal corresponding to the current provided when the additional rectification element is not connected to the resistor-side rectification element or the terminal-side rectification element and a signal corresponding to the current provided when the additional rectification element is connected to the resistor-side rectification element or the terminal-side rectification element, and a signal processing section configured to process a pixel signal on the basis of the temperature data. This produces an effect of processing a pixel signal by using accurate temperature data.

Additionally, in the second aspect, the signal processing section may include a parameter calculation section configured to calculate a parameter for correcting the temperature data on the basis of the temperature data and a predetermined set temperature, a parameter storage section configured to store the parameter, and a temperature characteristic correction section configured to correct the temperature data by using the stored parameter. This produces an effect of correcting errors in temperature data.

Additionally, in the second aspect, the electronic equipment may further include a pixel configured to generate the pixel signal, and a selector configured to select either the pixel signal or a temperature signal corresponding to the current and output the selected signal to the difference acquisition section. The difference acquisition section may convert the temperature signal into a digital signal and acquires the difference in a case where the temperature signal is selected, and the difference acquisition section may convert the pixel signal into a digital signal in a case where the pixel signal is selected. This produces an effect of measuring temperature data during capturing of image data.

### BRIEF DESCRIPTION OF DRAWINGS

FIG. 1 is a block diagram depicting a configuration example of an imaging apparatus according to a first embodiment of the present technology.

FIG. 2 is a block diagram depicting a configuration example of an image sensor according to the first embodiment of the present technology.

FIG. 3 is a block diagram depicting a configuration example of a column ADC according to the first embodiment of the present technology.

FIG. 4 is a circuit diagram depicting a configuration example of a comparator according to the first embodiment of the present technology.

FIG. 5 is a circuit diagram depicting a configuration example of a temperature signal output circuit according to the first embodiment of the present technology.

FIG. 6 is a block diagram depicting a configuration example of a signal processing section according to the first embodiment of the present technology.

FIG. 7 is a block diagram depicting a configuration example of a measurement circuit according to the first embodiment of the present technology.

FIG. 8 is a circuit diagram depicting a configuration example of the temperature signal output circuit to which a dummy switch is added, according to the first embodiment of the present technology.

FIG. 9 is a timing chart depicting an example of operations of the image sensor according to the first embodiment of the present technology.

FIG. 10 is a timing chart depicting an example of an AD (Analog to Digital) conversion operation performed on a pixel signal by the image sensor according to the first embodiment of the present technology.

FIG. 11 is a timing chart depicting an example of an AD conversion operation performed on a temperature signal by the image sensor according to the first embodiment of the present technology.

FIG. 12 depicts graphs for describing an example of temperature measurement results in the first embodiment of the present technology and in a comparative example.

FIG. 13 is a flowchart depicting an example of operations of the imaging apparatus according to the first embodiment of the present technology.

FIG. 14 is a flowchart depicting an example of parameter calculation processing according to the first embodiment of the present technology.

FIG. 15 is a flowchart depicting an example of temperature data generation processing according to the first embodiment of the present technology.

FIG. 16 is a flowchart depicting an example of temperature measurement processing according to the first embodiment of the present technology.

FIG. 17 is a circuit diagram depicting a configuration example of a temperature signal output circuit according to a second embodiment of the present technology.

FIG. 18 is a circuit diagram depicting a configuration example of a temperature signal output circuit according to a third embodiment of the present technology.

FIG. 19 is a circuit diagram depicting a configuration example of a temperature signal output circuit according to a fourth embodiment of the present technology.

FIG. 20 is a circuit diagram depicting a configuration example of a temperature signal output circuit according to a fifth embodiment of the present technology.

FIG. 21 is a circuit diagram depicting a configuration example of a temperature signal output circuit according to a sixth embodiment of the present technology.

FIG. 22 is a block diagram depicting an example of schematic configuration of a vehicle control system.

FIG. 23 is a diagram of assistance in explaining an example of installation positions of an outside-vehicle information detecting section and an imaging section.

### DESCRIPTION OF EMBODIMENTS

Modes for carrying out the present technology (hereinafter referred to as embodiments) will be described below. The description is given in the following order.
1. First embodiment (example in which an additional rectification element is connected in parallel)
2. Second embodiment (example in which an additional rectification element is connected in parallel and a current mirror circuit is omitted)
3. Third embodiment (example in which an additional rectification element is connected in parallel and a current-to-voltage conversion section is omitted)
4. Fourth embodiment (example in which an additional rectification element is connected in parallel and a current mirror circuit is omitted)
5. Fifth embodiment (example in which an additional rectification element is connected in parallel on a positive side and on a negative side)
6. Fourth embodiment (example in which diodes are connected in parallel as additional rectification elements)
7. Example of application to Mobile Body

### 1. First Embodiment

### [Configuration Example of Imaging Apparatus]

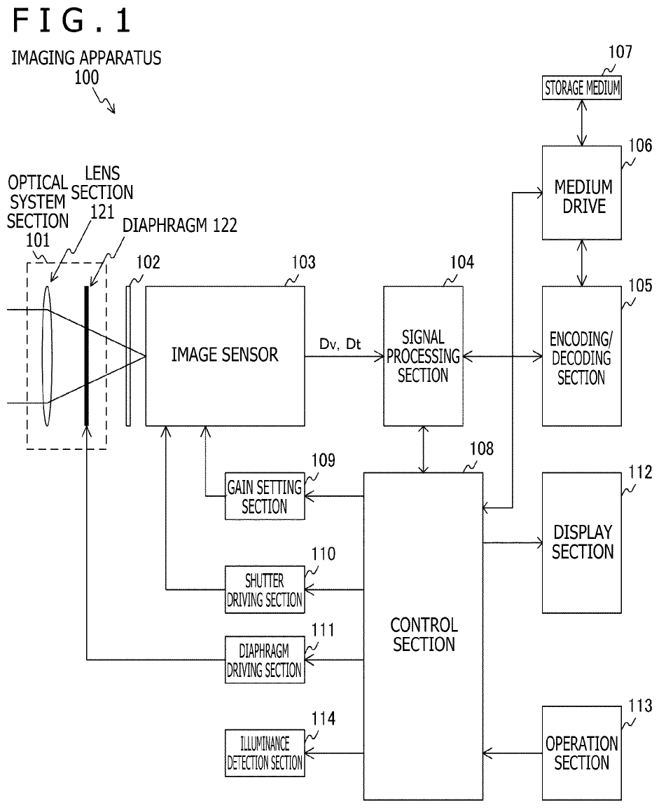

FIG. 1 is a block diagram depicting a configuration example of an imaging apparatus 100 according to a first embodiment of the present invention. The imaging apparatus 100 depicted in FIG. 1 can cause a storage medium to store a captured image as data in a moving image or still image format. Note that the configuration of the imaging apparatus 100 depicted in FIG. 1 is common to those of second to sixth embodiments of the present invention to be described below.

The imaging apparatus 100 depicted in FIG. 1 includes an optical system section 101, a filter 102, an image sensor 103, a signal processing section 104, an encoding/decoding section 105, and a medium drive 106. The imaging apparatus 100 further includes a control section 108, a gain setting section 109, a shutter driving section 110, a diaphragm driving section 111, an illuminance detection section 114, a display section 112, and an operation section 113.

The optical system section 101 executes optical processing on incident light. The optical system section 101 includes a lens section 121 and a diaphragm 122. The lens section 121 includes a predetermined number of imaging fixed lenses, a zoom lens, a focus lens, and the like. Although not depicted here, the zoom lens and the focus lens are driven to move along the optical axis direction of imaging light according to zoom control and focusing control. The diaphragm 122 is a mechanical section for adjusting the amount of imaging light passing through the lens section 121 and is driven by the diaphragm driving section 111 such that the size of an aperture corresponds to an f-number.

Light that has entered the optical system section 101 is formed into imaging light on a light receiving surface of the image sensor 103 via the filter 102. The filter 102 removes light components with wavelengths unnecessary for imaging, for example.

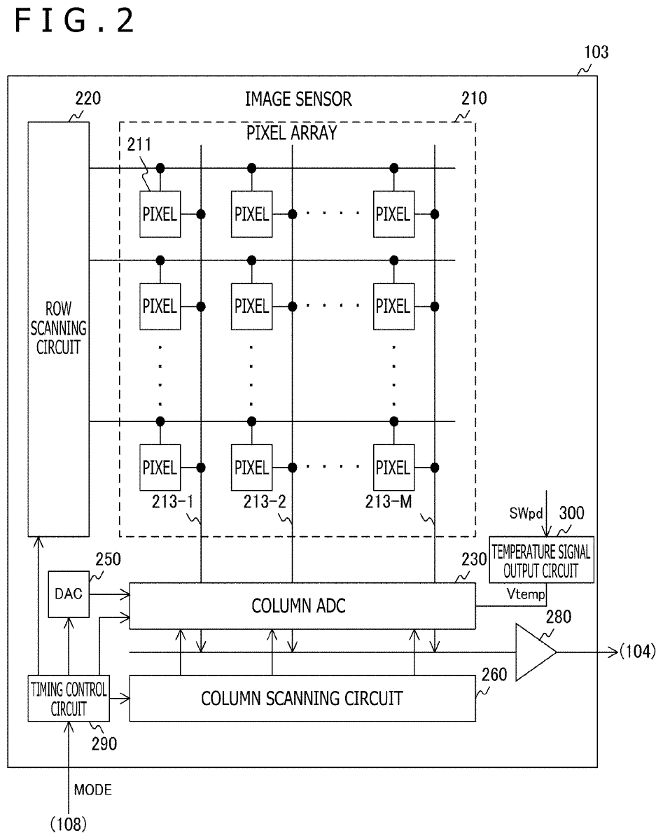

The image sensor 103 uses a solid imaging element to convert the imaging light passing through the optical system section 101 into an electric signal and outputs an image signal. In other words, the image sensor 103 performs photoelectric conversion. Known such image sensors include a CCD (Charge Coupled Device) sensor, a CMOS sensor, and the like. In the embodiments of the present invention, it is assumed that a CMOS sensor is employed as the image sensor. By being internally provided with an ADC (Analog to Digital Converter), the image sensor, which is a CMOS sensor herein, can be configured to output image data in a digital format as an image signal. Note that, in the embodiments of the present invention, the image sensor 103 outputs temperature data Dt along with image data. The temperature data indicates the temperature of an IC (Integrated Circuit) chip on which a circuit used as the image sensor 103 is mounted. An internal configuration example of the image sensor 103 that can output such image data and temperature data will be described below with reference to FIG. 2.

Pixel data Dv output from the image sensor 103 is input to the signal processing section 104. The signal processing section 104 executes required signal processing on the pixel data Dv for each pixel to generate image data in a moving image or still image format.

In a case where image data generated by the signal processing section 104 is to be recorded in a storage medium 107, the image data is output to the encoding/decoding section 105. The encoding/decoding section 105 uses a predetermined compression encoding scheme to execute compression encoding on the image data output from the signal processing section 104. After the compression encoding, for example, under the control of the control section 108, the encoding/decoding section 105 adds a header and the like to the image data and converts the image data into an image data format in which the data is compressed into a predetermined format. Then, the image data thus generated is transferred to the medium drive 106. The medium drive 106 writes the transferred image data to the storage medium 107 for storage. Note that, assuming that the storage medium 107 is, for example, in a removable form, the storage medium 107 may removably be attached to the medium drive 106. Alternatively, the storage medium 107 may be built into the imaging apparatus 100 in advance as is the case with, for example, an HDD (Hard Disc Drive).

Additionally, the imaging apparatus 100 can use image data generated by the signal processing section 104, to cause the display section 112 to display an image being captured, which is referred to as a through image. To achieve this, for example, image data in a moving image format generated by the signal processing section 104 is converted into image data with such a resolution that can be displayed on the display section 112, under the control of the control section 108, and the converted data is transferred to the display section 112 and displayed thereon. When a user views an image displayed in such a manner as described above, the image being captured at that time is displayed on the display section 112 as a moving image. In such a manner, the through image is displayed. Note that a part or all of the processing executed by the signal processing section 104 may be executed within the image sensor 103.

Additionally, the imaging apparatus 100 can reproduce image data recorded in the storage medium 107 and cause the display section 112 to display the corresponding image.

To achieve this, for example, according to an image reproduction operation performed on the operation section 113, the control section 108 designates image data and instructs the medium drive 106 to read the data from the storage medium 107. In response to the instruction, the medium drive 106 reads the designated image data from the storage medium 107 and transfers the read data to the encoding/decoding section 105.

For example, under the control of the control section 108, the encoding/decoding section 105 executes decoding processing corresponding to the compression encoding on the image data transferred from the medium drive 106 and transfers the resultant image data to the signal processing section 104 in this case. The signal processing section 104 converts the transferred image data into image data with a resolution suitable for display on the display section 112, for example, and transfers the resultant image data to the display section 112. Thus, the display section 112 reproduces and displays, as a moving image or a still image, the image of the image data stored in the storage medium 107.

In practice, the control section 108 includes, for example, a CPU (Central Processing Unit). Along with a ROM (Read Only Memory), a RAM (Random Access Memory), and the like, the control section 108 is configured as a microcomputer. Further, the control section 108 performs various types of control and processing operations in the imaging apparatus 100.

Under the control of the control section 108, the shutter driving section 110 controls an operation of reading pixel data from the image sensor 103 to implement an electronic shutter. For example, the shutter driving section 110 performs the control to change the shutter speed of the electronic shutter.

Under the control of the control section 108, the diaphragm driving section 111 changes the size of the aperture of the diaphragm 122. For example, the control section 108 can perform automatic exposure control (AE: Automatic Exposure). When the automatic exposure control is performed, the shutter driving section 110, the diaphragm driving section 111, and the gain setting section 109 are controlled to obtain such a shutter speed, size of aperture (f-number) of the diaphragm 122, and gain that correspond to the proper exposure determined.

The illuminance detection section 114 includes, for example, a photodiode or a phototransistor and detects illuminance.

The operation section 113 collectively represents various operators included in the imaging apparatus 100 and a signal output section that generates an operation signal corresponding to an operation performed on the operator and that outputs the operation signal to the control section 108. The control section 108 executes predetermined processing according to the operation signal received from the operation section 113. Thus, an operation of the imaging apparatus 100 based on the user operation is obtained.

Note that the imaging apparatus 100 is an example of electronic equipment recited in the claims.

### [Configuration Example of Image Sensor]

FIG. 2 is a block diagram depicting a configuration example of the image sensor 103. As described above, a CMOS sensor is employed as the image sensor 103 of the present embodiment.

As depicted in FIG. 2, the image sensor 103 includes a pixel array 210, a row scanning circuit 220, a column ADC 230, and a DAC (Digital to Analog Converter) 250. The image sensor 103 further includes a temperature signal output circuit 300, a column scanning circuit 260, a buffer amplifier 280, and a timing control circuit 290. The pixel array 210 is formed, for example, on one chip (semiconductor substrate), and the above-described sections and circuits depicted in FIG. 2 other than the pixel array 210 are also formed integrally on the same chip as that of the pixel array 210.

In the pixel array 210, a large number of pixels 211 are arranged in a matrix with N rows and M columns. Here, N and M are integers. Although an illustration of a configuration of a portion corresponding to the pixel 211 is omitted here, the pixel includes, for example, the following elements. Specifically, the pixel includes, for example, a photoelectric conversion element such as a photodiode, and a transfer transistor that transfers, to an FD (Floating Diffusion) section, a charge obtained through photoelectric conversion by a photoelectric conversion element. The pixel further includes a reset transistor that controls the potential of the FD section and an amplifying transistor that outputs a signal corresponding to the potential of the FD section. Such a configuration includes three transistors and is thus referred to as a three-transistor configuration or the like. Additionally, instead of the three-transistor configuration, a four-transistor configuration that is further provided with a select transistor for selecting a pixel can also be employed.

As for an arrangement of the pixels 211 in a column (vertical) direction in the pixel array 210, a column signal line 213-1 is connected to each of the pixels 211 arranged in the first column. Similarly, column signal lines 213-2 to 213-M are connected to the corresponding pixels 211 arranged in the second to m-th columns.

The column ADC 230 converts pixel signals output from the column signal lines 213-1 to 213-M into digital signals and outputs the digital signals as image data. Additionally, the column ADC 230 generates temperature data Dt on the basis of an analog temperature signal Vtemp from the temperature signal output circuit 300.

The DAC 250 generates a predetermined reference signal by DA (Digital to Analog) conversion. As a reference signal, for example, a saw-tooth-like ramp signal is generated. The DAC 250 supplies the ramp signal to the column ADC 230.

Similarly to the row scanning circuit 220, the column scanning circuit 260 includes a shift register, a decoder, or the like. The column scanning circuit 260 performs column scanning by outputting a column control signal at a timing according to a column scanning timing signal output from the timing control circuit 290. At the timing when scanning is performed, the pixel data Dv and the temperature data Dt are output to the buffer amplifier 280. The pixel data Dv and the temperature data Dt are output to the signal processing section 104 via the buffer amplifier 280.

On the basis of an input master clock, the timing control circuit 290 generates and outputs a required clock, timing clock, and the like to appropriate sections.

Additionally, a mode signal MODE is input to the timing control circuit 290. The mode signal MODE is a signal indicating an operation mode of the imaging apparatus 100 and is generated, for example, by the control section 108. The mode of the imaging apparatus 100 includes a calibration mode and an imaging mode.

In this regard, the calibration mode is a mode in which a parameter for correcting the temperature data Dt is calculated, while the imaging mode is a mode in which image data is captured. In the imaging mode, the temperature data Dt is simultaneously generated and is corrected using a parameter.

Additionally, in the calibration mode and the imaging mode, the timing control circuit 290 supplies a control signal SWpd to the temperature signal output circuit 300 to cause the temperature signal output circuit 300 to output a temperature signal Vtemp.

According to the control signal SWpd, the temperature signal output circuit 300 outputs the temperature signal Vtemp to the column ADC 230.

### [Configuration Example of Column ADC]

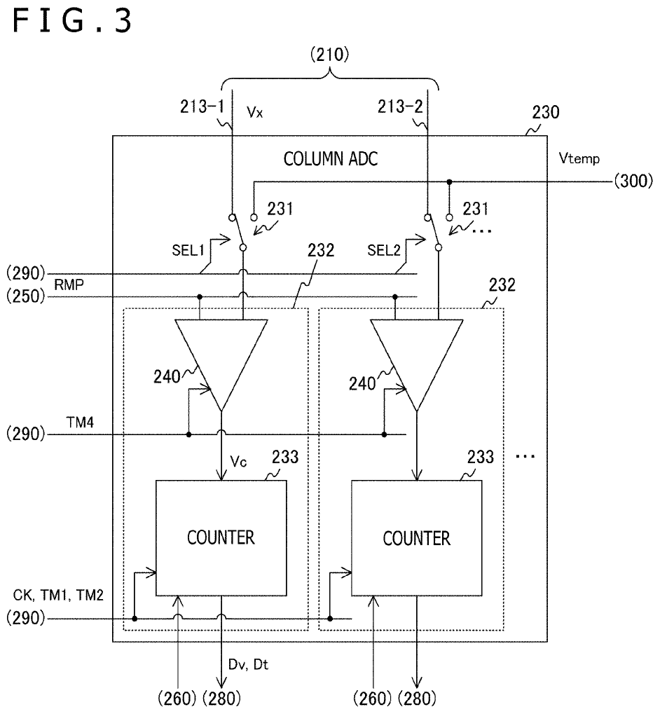

FIG. 3 is a block diagram depicting a configuration example of the column ADC 230 according to the first embodiment of the present technology. In the column ADC 230, a plurality of selectors 231 and a plurality of ADCs 232 are arranged. Each of the selectors 231 and each of the ADCs 232 are provided for corresponding one of the columns within the pixel array 210. When M denotes the number of columns, M selectors 231 and M ADCs 232 are provided.

The selector 231 selects either a pixel signal Vx or the temperature signal Vtemp from the corresponding column. A select signal SELm from the timing control circuit 290 is input to the m-th (m is an integer of 1 to M) selector 231. According to the select signal SELm, the m-th selector 231 selects either the pixel signal Vx or the temperature signal Vtemp and outputs the selected signal to the corresponding ADC 232.

The timing control circuit 290 uses the select signal SELm to cause only any one of the M selectors 231 to select the temperature signal Vtemp and cause the remaining selectors 231 to select the pixel signal Vx.

The ADC 232 AD-converts a signal from the selector 231. Since only any one of the M selectors 231 selects the temperature signal Vtemp, corresponding one of the M ADCs 232 AD-converts the temperature signal Vtemp while the remaining ADCs 232 AD-convert the pixel signal Vx.

Each of the ADCs 232 includes a comparator 240 and a counter 233. The comparator 240 compares a signal from the selectors 231 with a reference signal RMP from the DAC 250. The comparator 240 supplies the counter 233 with an output signal Vc representing a comparison result. Additionally, a timing signal TM4 from the timing control circuit 290 is input to the comparator 240. The timing signal TM4 is a signal indicating a timing when the comparator 240 is initialized.

The counter 233 counts a counter value in synchronism with a clock signal CK over a period of time until the output signal Vc is inverted. Additionally, the clock signal CK and timing signals TM1 and TM2 from the timing control circuit 290 are input to the counter 233. The timing signal TM1 is a signal indicating a timing of starting a count-down operation, while the timing signal TM2 is a signal indicating a timing of starting a count-up operation.

Each time a row is scanned, the timing control circuit 290 causes each of the ADCs 232 to perform AD conversion. In the AD conversion for each row, the timing control circuit 290 uses the timing signal TM1 to initialize the comparator 240 and sequentially supplies the timing signals TM1 and TM2 to cause the counter 233 to count down and up in order.

In this regard, the pixel signal Vx includes a P phase level and a D phase level. The P phase level is a level of the pixel signal Vx provided when the FD section of the pixel is initialized, and the D phase level is a level of the pixel signal Vx provided when a charge is transferred from the photoelectric conversion element to the FD section in the pixel.

The timing control circuit 290 causes the counter 233 to count down during a period of time when the P phase level is output, and causes the counter 233 to count up during a period of time when the D phase level is output. Thus, the ADC 232 calculates a difference between the P phase level and the D phase level of the pixel signal Vx. Processing in which a pixel signal is sampled a plurality of times in such a manner as described above is referred to as CDS (Correlated Double Sampling) processing.

Note that, while the ADC 232 counts down and up in order, the ADC 232 may count down only or count up only. In this case, it is sufficient to add a CDS circuit that calculates a difference in counter value, to a stage following the ADC 232.

Additionally, the selector 231 is disposed in each column, but the present technology is not limited to this configuration. For example, with the selector 231 disposed in only any one of the columns, pixels in the other columns can be connected directly to the ADC 232 in the column in which the selector 231 is disposed. Alternatively, with no selectors 231 disposed in the columns, the temperature signal output circuit 300 can be connected to the ADC 232 in any one of the columns, and pixels in the other columns can be connected to the ADC 232 to which the temperature signal output circuit 300 is connected. Otherwise, a dedicated ADC for generating temperature data can be added. In this case, it is sufficient to dispose M+1 ADCs in M columns and connect any one of the ADCs to the temperature signal output circuit 300.

### [Configuration Example of Comparator]

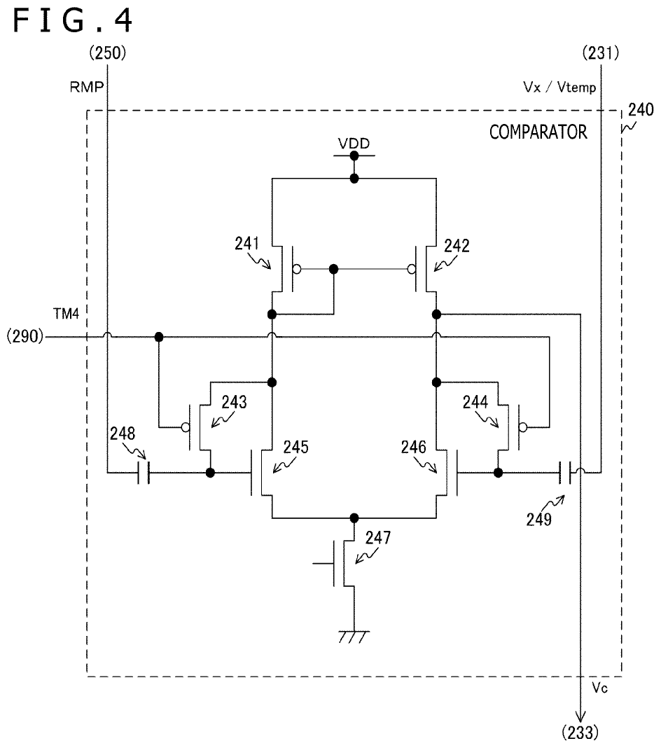

FIG. 4 is a circuit diagram depicting a configuration example of the comparator 240 according to the first embodiment of the present technology. The comparator 240 includes pMOS (p-channel Metal Oxide Semiconductor) transistors 241 to 244 and nMOS (n-channel MOS) transistors 245 to 247. Further, the comparator 240 includes capacitors 248 and 249.

A source of the nMOS transistor 245 and a source of the nMOS transistor 246 are connected to each other and share a common connection, and the connection point between the sources is grounded via a drain and a source of the nMOS transistor 247. Among signals input to the comparator 240, the reference signal RMP is input to a gate of the nMOS transistor 245 via the capacitor 248, while a signal from the selector 231 (pixel signal Vx or temperature signal Vtemp) is input to a gate of the nMOS transistor 246 via the capacitor 249.

Further, a drain of the nMOS transistor 245 is connected to a power supply voltage VDD via the pMOS transistor 241. A source of the pMOS transistor 241 is connected to the power supply voltage VDD, and a drain of the pMOS transistors 241 is connected to the source of the nMOS transistor 245. Additionally, the drain and a gate of the pMOS transistor 241 are short-circuited.

In addition, a drain of the nMOS transistors 246 is connected to the power supply voltage VDD via the pMOS transistor 242. A source of the pMOS transistor 242 is connected to the power supply voltage VDD, and a drain of the pMOS transistor 242 is connected to the source of the nMOS transistor 246. A connection node between the pMOS transistor 242 and the nMOS transistor 246 outputs an output signal Vc.

Additionally, the timing signal TM4 is input to a gate of the pMOS transistor 243 and to a gate of the pMOS transistor 244 in a branching manner. In addition, a drain and a source of the pMOS transistor 243 are respectively connected to the drain and the gate of the nMOS transistor 245. Similarly, a drain and a source of the pMOS transistor 244 are respectively connected to the drain and the gate of the nMOS transistor 246.

In the above-described connection configuration, the circuit in the comparator 240 constitutes a differential amplification circuit. Gate potentials of the nMOS transistors 245 and 246 forming the differential amplification circuit individually include, for example, DC (Direct Current) offset components included in the pixel signal Vx and the reference signal RMP. Additionally, the gate potentials include, for example, offset potentials mainly caused by variations in thresholds (Vth) of the nMOS transistors 245 and 246 themselves. However, when the timing signal TM4 of a low level is input, operating points of the nMOS transistors 245 and 246 are reset to drain potentials, substantially cancelling the above-described offset potentials. This makes the potentials of two input terminals of the comparator 240 substantially the same. Note that an operation of resetting the input terminals of the comparator 240 to the same potential in such a manner as described above is also referred to as “input terminal potential reset” hereinafter. Execution of the input terminal potential reset enables, in an actual operation, a reduction in the amount of time required to compare pixel signal Vx with the reference signal RMP, for example.

[Configuration Example of Temperature Signal Output Circuit]

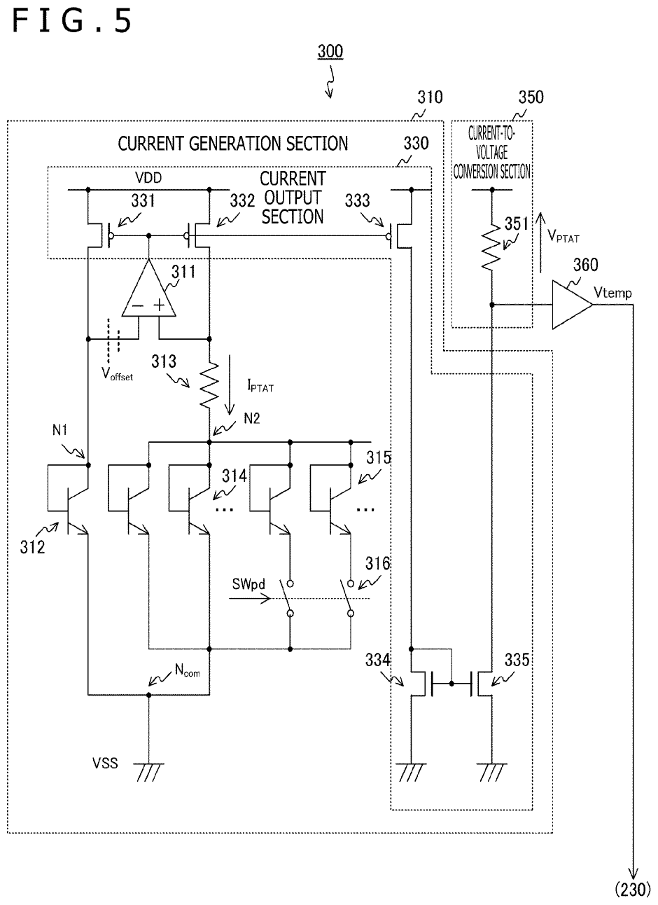

FIG. 5 is a circuit diagram depicting a configuration example of the temperature signal output circuit 300 according to the first embodiment of the present technology. The temperature signal output circuit 300 includes a current generation section 310, a current-to-voltage conversion section 350, and a voltage buffer 360.

The current generation section 310 generates a current I_{PTAT} for measuring temperature. The current generation section 310 includes an operational amplifier 311, bipolar transistors 312, 314, and 315, a resistor 313, a switch 316, and a current output section 330. For example, npn transistors are used as the bipolar transistors 312, 314, and 315.

The operational amplifier 311 outputs an output voltage corresponding to a difference between the terminal voltages of an inverting input terminal (−) and a non-inverting input terminal (+).

Here, regarding an ideal operational amplifier, in a case where there is a zero difference in voltage between input terminals, an output voltage is usually zero. However, in actuality, due to a variation in the characteristics of the transistors in the operational amplifier or the like, the output voltage is often prevented from being zero even with a zero difference in voltage between the input terminals. An offset output voltage generated when there is a zero difference in voltage between the input terminals can be converted into a difference in voltage between the input terminals that is required to make the output voltage zero, and such a value is referred to as an input offset voltage. In FIG. 5, assuming that a positive input offset voltage V_{offset} is generated on a negative side, the voltage is represented by a graphic symbol with a dotted line.

Each of the bipolar transistors 312, 314, and 315 includes a base and a collector that are short-circuited (what is called diode-connected). The number of the bipolar transistors 312, the number of the bipolar transistors 314, and the number of the bipolar transistors 315 are optional. However, the number of the bipolar transistors 314 or 315 is preferably larger than that of the bipolar transistors 312. For example, it is hereinafter assumed that the number of the bipolar transistors 312 is one, that the number of the bipolar transistors 314 is K (K is an integer), and that the number of the bipolar transistors 315 is L (L is an integer). Note that the number of the bipolar transistors 312 can also be two or more. In a case of two or more bipolar transistors 312, the bipolar transistors 312 are connected in parallel with each other. This also applies to the bipolar transistors 314 and 315. Two or more bipolar transistors 314 or 315 are connected in parallel with each other.

Additionally, according to the control signal SWpd supplied from the timing control circuit 290, the switch 316 connects the bipolar transistor 315 in parallel with the bipolar transistors 314. The switch 316 is disposed in each of the bipolar transistors 315.

Additionally, the collector of the bipolar transistor 312 is connected to the non-inverting input terminal (−) of the operational amplifier 311. A node for the collector is assumed to be a node N1.

One end of the resistor 313 is connected to the non-inverting input terminal (+) of the operational amplifier 311. The other end of the resistor 313 is connected to the collectors of the bipolar transistors 314 and 315 which share a common connection. A node for the collectors is assumed to be a node N2. Additionally, emitters of the bipolar transistors 312 and 314 are connected to a common node N_{com} of a ground potential VSS and share a common connection. An emitter of the bipolar transistor 315 is connected to the common node N_{com} via the switch 316.

Additionally, the current output section 330 outputs the current I_{PTAT} corresponding to the output voltage output from the operational amplifier 311. The current output section 330 includes pMOS transistors 331 to 333 and nMOS transistors 334 and 335.

The pMOS transistors 331 is interposed between the power supply voltage VDD and the collector of the bipolar transistor 312, and a gate of the pMOS transistor 331 is connected to an output terminal of the operational amplifier 311. The pMOS transistor 331 feeds back the current I_{PTAT} to the bipolar transistor 312.

The pMOS transistor 332 is interposed between the power supply voltage VDD and the resistor 313, and a gate of the pMOS transistor 332 is connected to the output terminal of the operational amplifier 311. The pMOS transistor 332 feeds back the current I_{PTAT} to the bipolar transistors 314 and 315 via the resistor 313.

The pMOS transistor 333 is interposed between the power supply voltage VDD and a drain of the nMOS transistor 334, and a gate of the pMOS transistor 333 is connected to the output terminal of the operational amplifier 311. The pMOS transistor 333 outputs the current I_{PTAT} to an input node of a current mirror circuit to be described below.

Note that the pMOS transistor 331 is an example of a first P-type transistor recited in the claims and that the pMOS transistor 332 is an example of a second P-type transistor recited in the claims. The pMOS transistor 333 is an example of a third P-type transistor recited in the claims.

Additionally, the drain and a gate of the nMOS transistor 334 are short-circuited. The gate of the nMOS transistor 334 and a gate of the nMOS transistor 335 are connected to each other, and each of sources of the nMOS transistors 334 and 335 is connected to the ground potential VSS. A drain of the nMOS transistor 335 is connected to the current-to-voltage conversion section 350. Such connections allow the nMOS transistors 334 and 335 to function as a current mirror circuit that outputs, to the current-to-voltage conversion section 350, a current input to the drain of the nMOS transistor 334. The drain of the nMOS transistor 334 corresponds to the input node of the current mirror circuit.

The current-to-voltage conversion section 350 converts the current I_{PTAT} into a voltage V_{PTAT}. For example, a resistor 351 is disposed in the current-to-voltage conversion section 350. The resistor 351 is interposed between the power supply voltage VDD and the drain of the nMOS transistors 335.

The voltage buffer 360 outputs a signal for the voltage V_{PTAT} of a connection node between the resistor 351 and the nMOS transistor 335 to the column ADC 230 as the temperature signal Vtemp.

In this regard, the timing control circuit 290 sets the switch 316 to be in an open state during a period of time when the P phase level is converted, and sets the switch 316 to be in a closed state during a period of time when the D phase level is converted. I_{PTAT_p} refers to the current I_{PTAT} provided when the switch 316 is in the open state, and a current I_{PTAT_d} corresponds to the current I_{PTAT} provided when the switch 316 is in the closed state.

In a case where the switch 316 is in the open state, the voltage V1 of the node N1 on the negative side is expressed by the following equation.

V1=(kT/q)(I_{PTAT}_p/Is) Equation 1

where k is a Boltzmann constant, and the unit of the Boltzmann constant is Joule per Kelvin (J/K). T is an absolute temperature, and the unit of the absolute temperature is, for example, Kelvin (K). Represented by q is an electron charge, and the unit of the electron charge is, for example, coulomb (c). Is is a saturation current in the bipolar transistor, and the unit of the saturated current is, for example, ampere (A).

Additionally, in the case where the switch 316 is in the open state, the voltage V2 of the node N2 on the positive side is expressed by the following equation.

V2=(kT/q){I_{PTAT_p}/(K·Is)} Equation 2

In addition, with an input offset voltage V_{offset} taken into account, a voltage Vᵢₙ₋ of the non-inverting input terminal (−) of the operational amplifier 311 is expressed by the following equation on the basis of Equation 1.

$${V}_{in -} = V 1 + {V}_{offset} = ( kT / q ) ( {I}_{PTAT\_p} / Is ) + {V}_{offset} \qquad Equation 3$$

On the other hand, a voltage Vᵢₙ₊ of the non-inverting input terminal (+) of the operational amplifier 311 is expressed by the following equation on the basis of Equation 2.

$${V}_{in +} = V 2 + R \cdot {I}_{PTAT\_p} = ( kT / q ) \{ ( {I}_{PTAT\_p} / K \cdot Is ) \} + R \cdot {I}_{PTAT\_P} \qquad Equation 4$$

where R is a resistance value of the resistor 313.

In this regard, with use of a negative feedback circuit including the operational amplifier 311 and the current output section 330, the current I_{PTAT_p} is adjusted such that a difference in voltage between the input terminals of the operational amplifier 311 becomes substantially zero. Thus, the following equation holds true.

Vᵢₙ₋=Vᵢₙ₊ Equation 5

By transforming Equation 5 by substituting Equations 3 and 4 into Equation 5, the following equation is obtained.

I_{PTAT_p}=(1/R){V_{offset}+(kT/q)·ln(K)} Equation 6

where “ln( )” is a function that returns the logarithm of a value in parentheses.

Assuming that R is a resistance value of the resistor 351 as is the case with the resistor 313 and that V_{PTAT_p} is the voltage V_{PTAT} provided when the switch 316 is in the open state, the equation below is obtained from Equation 6. Note that the resistance value of the resistor 351 may differ from the resistance value of the resistor 313.

$${V}_{PTAT\_p} = R \cdot {I}_{PTAT\_p} = {V}_{offset} + ( kT / q ) \cdot ln ( K ) \qquad Equation 7$$

Next, in a case where the switch 316 is in the closed state, L bipolar transistors 315 are connected in parallel with the bipolar transistor 314. The voltage V2 of the node N2 on the positive side at this time is expressed by the following equation.

V2=(kT/q){I_{PTAT_d}/(K·Is+L·Is)} Equation 8

On the basis of Equation 8, the voltage Vᵢₙ₊ is expressed by the following equation.

$${V}_{i n +} = V 2 + R \cdot {I}_{PTAT\_d} = ( kT / q ) {\{}_{IPTAT\_d} / ( K \cdot Is + L \cdot Is ) \} + R \cdot {I}_{PTAT\_d} \qquad Equation 9$$

By transforming Equation 5 by substituting Equations 3 and 9 into Equation 5, the following equation is obtained,

I_{PTAT_d}=(1/R)

{V_{offset}+(kT/q)·ln(K+L)} Equation 10

Assuming that V_{PTAT_d} is the voltage V_{PTAT} provided when the switch 316 is in the closed state, the following equation is obtained from Equation 10.

$${V}_{PTAT\_d} = R \cdot {I}_{PTAT\_d} = {V}_{offset} + ( kT / q ) \cdot ln ( K + L ) \qquad Equation 11$$

The ADC 232 in the subsequent stage AD-converts a difference between the voltage V_{PTAT_p} and the voltage V_{PTAT_d} to generate temperature data Dt. The value of the temperature data Dt is expressed by the following equation on the basis of Equations 7 and 11.

$$Dt = {V}_{PTAT\_d} - {V}_{PTAT\_p} = ( kT / q ) \cdot ln \{ ( K + L ) / K \} \qquad Equation 12$$

K and L are fixed values, and thus, the temperature data Dt has a value that is linear with respect to the absolute temperature T according to Equation 12. Additionally, taking a difference eliminates components of the input offset voltage.

Note that a base-emitter voltage of diode-connected bipolar transistors varies depending on temperature and that even a configuration including only bipolar transistors can thus be used as a temperature sensor. However, the base-emitter voltage has a non-linear characteristic with respect to temperature, and thus, sufficient measurement accuracy cannot be achieved by a configuration including only bipolar transistors.

If the operational amplifier 311 is used, a voltage V_{PTAT_p} that is linear with respect to temperature can be obtained according to Equation 7. However, components of the input offset voltage are present in the voltage V_{PTAT_p} as illustrated on the right side of Equation 7. Thus, if the voltage V_{PTAT_p} is directly converted into temperature data Dt without the bipolar transistor 315 and the switch 316 being provided, a measurement error is caused by the input offset voltage.

Thus, the image sensor 103 is provided with the bipolar transistor 315 and the switch 316 to change the number of parallel connections on the positive side and to acquire the difference between the voltage V_{PTAT} before changing and the voltage V_{PTAT} after changing. Acquisition of the difference allows components of the input offset voltage to be removed from the temperature data Dt as illustrated in Equation 12. This allows temperature measurement accuracy to be improved.

Note that, although the switch 316 is disposed between the emitter of the bipolar transistor 315 and the common node N_{com}, this configuration is not restrictive. For example, the switch 316 can be disposed between the collector of the bipolar transistor 315 and the resistor 313. Additionally, the switches can be disposed both on the emitter side of the bipolar transistor 315 and on the collector side of the bipolar transistor 315.

Additionally, while the diode-connected bipolar transistors 312, 314, and 315 are disposed, diodes can also be disposed instead of the transistors as described below as long as the diodes function as rectification elements.

Additionally, the bipolar transistor 312 is connected to the inverting input terminal (−) of the operational amplifier 311, whereas the resistor 313 is connected to the non-inverting input terminal (+) of the operational amplifier 311. However, the present embodiment is not limited to this configuration. The resistor 313 can be connected to the inverting input terminal (−), whereas the bipolar transistors 312 can be connected to the non-inverting input terminal (+).

Further, the switches 316 connect the bipolar transistors 315 in parallel with the bipolar transistors 314, but the present embodiment is not limited to this configuration. The bipolar transistors 315 and the switches 316 can be disposed on the negative side, and the switches 316 can connect the bipolar transistors 315 in parallel with the bipolar transistor 312.

### [Configuration Example of Signal Processing Section]

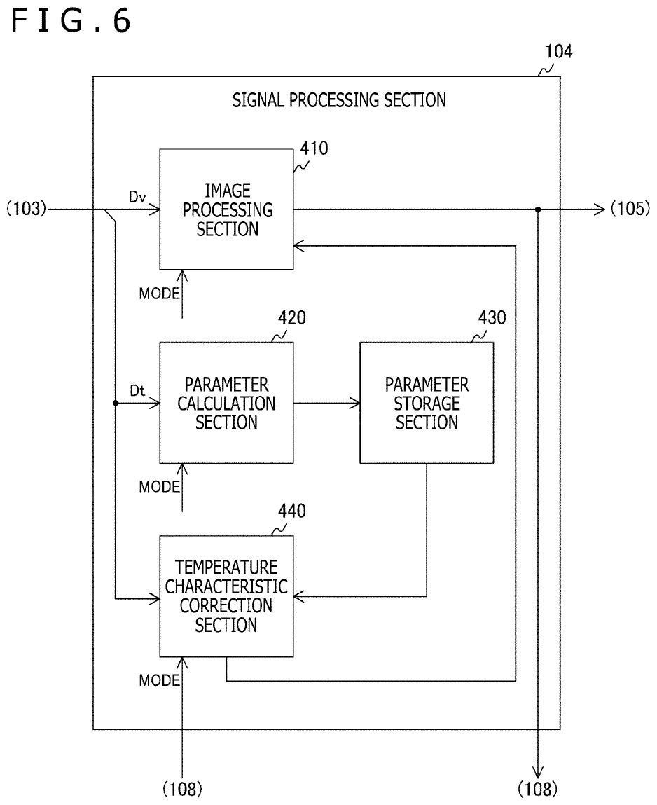

FIG. 6 is a block diagram depicting a configuration example of the signal processing section 104 according to the first embodiment of the present technology. The signal processing section 104 includes an image processing section 410, a parameter calculation section 420, a parameter storage section 430, and a temperature characteristic correction section 440. A mode signal MODE is input to each of the image processing section 410, the parameter calculation section 420, and the temperature characteristic correction section 440.

In the imaging mode, the image processing section 410 executes predetermined image processing on image data in which pieces of pixel data Dv are arranged. For example, various processing operations such as white balance correction processing and demosaic processing are executed. The image processing section 410 outputs the processed image data to the encoding/decoding section 105 and the control section 108. Additionally, the image processing section 410 can perform various corrections by using the temperature data Dt, as needed.

For example, in the image sensor, a leakage phenomenon in which a signal charge held in the pixels leaks toward the signal line as a dark current poses a problem. Such dark current components cause image degradation. Thus, processing is executed to reduce the dark current components. In this case, it is known that the dark current component has such a characteristic that the amount of the dark current varies with temperature. Thus, the image processing section 410 can correct the amount of the dark current detected according to the temperature indicated by the temperature data Dt and execute processing for reducing the dare current.

Additionally, in correction processing for a defective pixel, for example, whether or not the pixel is defective can be determined on the basis of the level of the pixel signal Vx. However, the pixel signal Vx at this time has such a characteristic that the level of the pixel signal Vx varies with temperature. Therefore, when defective pixels are to be corrected, the image processing section 410 can correct the signal level according to the temperature indicated by the temperature data Dt and then determine whether or not the pixel is defective.

Additionally, the temperature data Dt is generated during capturing of image data, as described above, and thus has a real time property. Accordingly, in signal processing such as dark current reduction processing and defective pixel correction processing, the temperature data Dt can be used to execute the signal processing such that the signal follows an actual variation in temperature at that time. This produces a high effect of reducing the dark current and a high effect of correcting defective pixels.

Note that the image sensor 103 can also output the temperature data Dt to the outside. The temperature data Dt output to the outside is used to stabilize the operation of the imaging apparatus 100 at high temperature, for example, by stopping capturing image data when the temperature rises.

The parameter calculation section 420 calculates, in the calibration mode, a parameter for correcting temperature data Dt as a temperature calculation parameter. In the calibration mode, the actual temperature is set to a test temperature. The parameter calculation section 420 acquires the temperature data Dt and acquires, as a measurement error, a difference between the temperature indicated by the data and the test temperature. The parameter calculation section 420 varies the test temperature to acquire a measurement error a plurality of times, and obtains a function indicating the relation between the temperature and the measurement error. The parameter calculation section 420 causes the parameter storage section 430 to store coefficients of the function as temperature calculation parameters.

The temperature characteristic correction section 440 corrects the temperature data Dt in the imaging mode. The temperature characteristic correction section 440 reads the temperature calculation parameters from the parameter storage section 430 and uses the parameters to correct the temperature data Dt. By using the temperature calculation parameters, measurement errors caused by factors other than the input offset voltage are corrected. The corrected temperature data Dt is supplied to the image processing section 410 and the like.

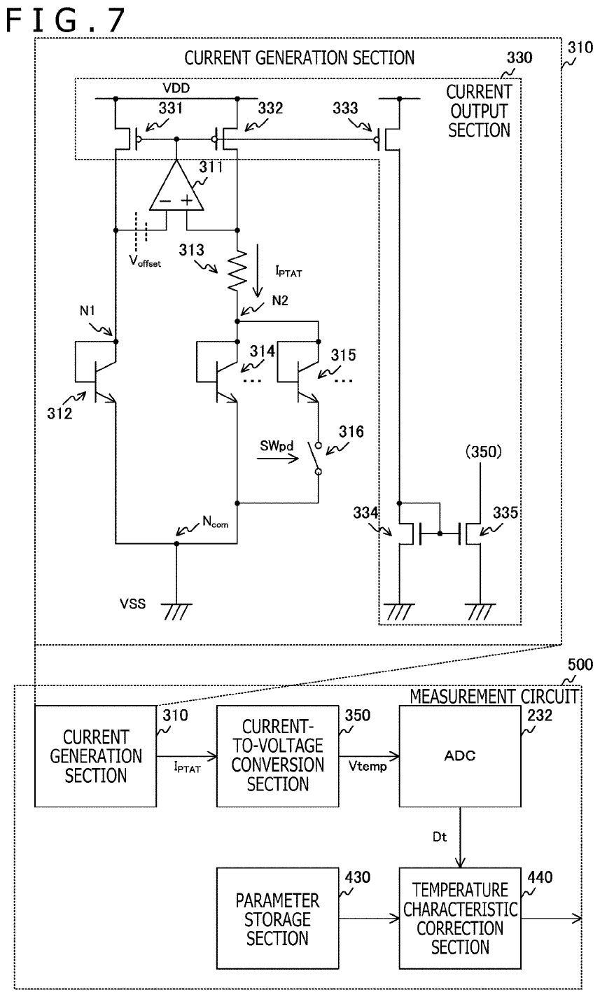

FIG. 7 is a block diagram depicting a configuration example of a measurement circuit according to the first embodiment of the present technology. A circuit that includes the current generation section 310 and the current-to-voltage conversion section 350 in the temperature signal output circuit 300, the ADC 232, and the parameter storage section 430 and the temperature characteristic correction section 440 in the signal processing section 104 functions as a measurement circuit 500 for measuring temperature.

Additionally, the current generation section 310 includes the operational amplifier 311, the bipolar transistors 312, 314, and 315, the resistor 313, the switch 316, and the current output section 330, as described above.

The operational amplifier 311 having a pair of input terminals outputs an output voltage corresponding to a difference between terminal voltages of the pair of input terminals. One of the input terminals is connected to one end of the resistor 313, and the other end of the input terminals is connected to the bipolar transistor 312. The bipolar transistor 314 is connected to the other end of the resistor 313. Note that the bipolar transistor 312 is an example of a terminal-side rectification element recited in the claims and that the bipolar transistor 314 is an example of a resistor-side rectification element recited in the claims.

Additionally, the switch 316 connects the bipolar transistor 315 in parallel with either the bipolar transistor 312 or the bipolar transistors 314 (for example, the bipolar transistors 314). The current output section 330 feeds back, to the resistor 313 and the like, a current corresponding to the output voltage from the operational amplifier 311. Note that the bipolar transistor 315 is an example of an additional rectification element recited in the claims.

The current-to-voltage conversion section 350 converts the current I_{PTAT} into a voltage. Then, the ADC 232 acquires, as the temperature data Dt, a difference between a voltage corresponding to the current I_{PTAT_p} provided when the bipolar transistor 315 is not connected with the bipolar transistor 312 or 314 and a voltage corresponding to the current I_{PTAT_d} provided when the bipolar transistor 315 is connected with the bipolar transistor 312 or 314.

When the ADC 232 acquires the difference, components of the input offset voltage can be removed from the temperature data Dt as illustrated in Equation 12. This allows the temperature measurement accuracy to be improved. Note that the ADC 232 is an example of a difference acquisition section recited in the claims.

Note that, while the ADC 232 AD-coverts a voltage, the ADC 232 AD can also AD-convert a current. In this case, the current-to-voltage conversion section 350 is unnecessary. Additionally, although the measurement circuit 500 in FIG. 7 is provided in the imaging apparatus 100, the measurement circuit 500 can also be disposed in a circuit or electronic equipment other than the imaging apparatus 100.

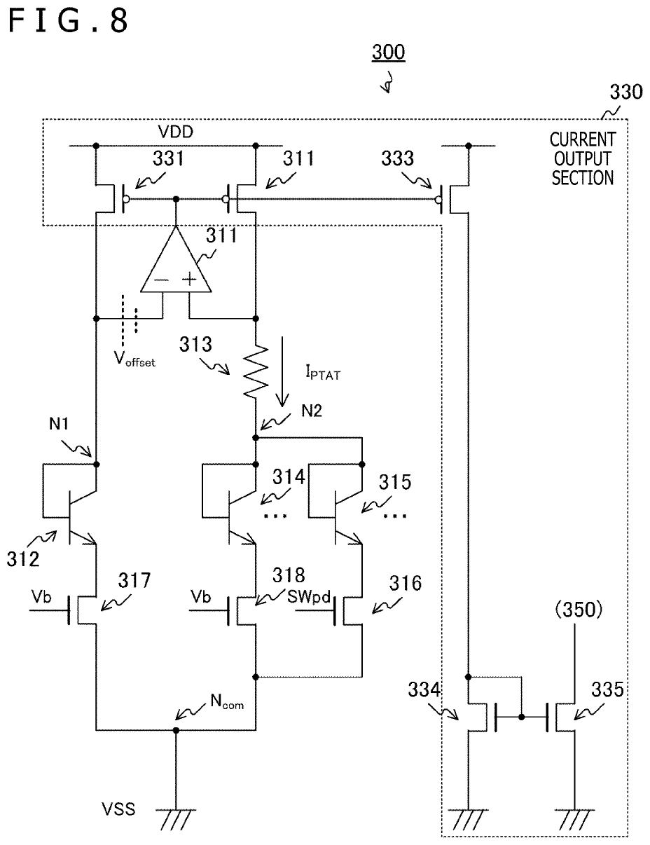

Additionally, no element is disposed between the common node Ncom and the bipolar transistors 312 and 314, but dummy switches 317 and 318 can be disposed between the common node Ncom and the bipolar transistors 312 and 314 as illustrated in FIG. 8. As the dummy switches 317 and 318 and the switch 316, transistors of an identical polarity (nMOS transistors or the like) are disposed. A bias voltage Vb is input to gates of the dummy switches 317 and 318 to fix the dummy switches 317 and 318 to an on-state. Disposing the dummy switches 318 and 318 in such a manner as described above makes the potentials of emitters of the bipolar transistors equal to each other, allowing measurement accuracy to be increased.

### [Operation Example of Image Sensor]

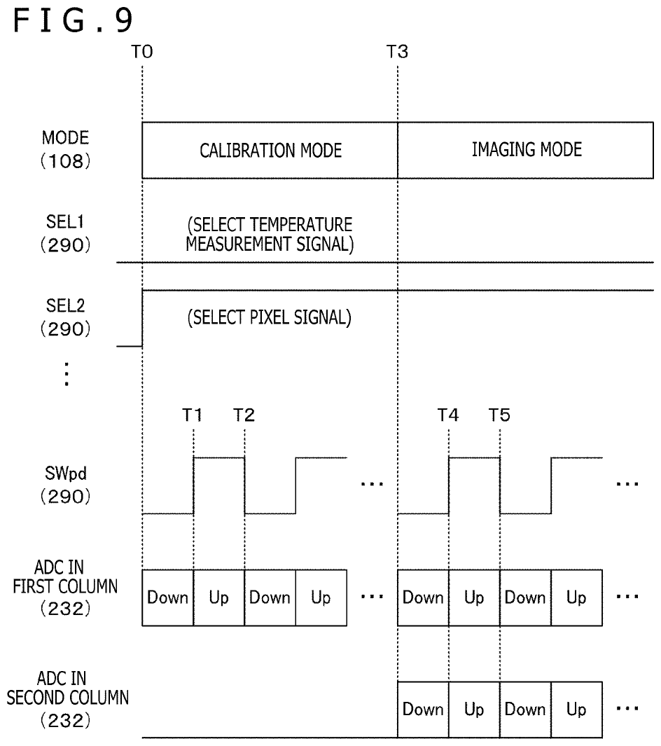

FIG. 9 is a timing chart depicting an example of operations of the image sensor 103 according to the first embodiment of the present technology. The timing control circuit 290 uses a select signal SEL1 to cause the selector 231 in the first column to select the temperature signal as an AD conversion target. Additionally, the timing control circuit 290 uses a select signal SEL2 or the like to cause the selectors 231 in the second and subsequent columns to select the pixel signal as an AD conversion target. Note that the column in which the temperature signal is selected can be changed every certain period of time.

It is assumed that the calibration mode is set at timings T0 to T3. In the calibration mode, during a P phase period from the timing T0 to the timing T1, the timing control circuit 290 supplies, for example, the control signal SWpd of a low level to the switch 316 to set the switch 316 to the open state. Additionally, during a D phase period from the timing T1 to the timing T2, the timing control circuit 290 supplies, for example, the control signal SWpd of a high level to the switch 316 to set the switch 316 to the closed state. After the timing T2, the control signal SWpd is controlled to be the high level and the low level alternately.

Additionally, the ADC 232 in the first column counts down during the P phase period and counts up during the D phase period to generate temperature data Dt. On the other hand, the ADCs 232 in the second and subsequent columns stop the count operation in the calibration mode.

It is assumed that the imaging mode is then set at the timing T3 or later. In the imaging mode, the timing control circuit 290 supplies the control signal SWpd of the low level during the P phase period from the timing T3 to the timing T4 and supplies the control signal SWpd of the high level during the D phase period from the timing T4 to the timing T5. At the timing T5 or later, the control signal SWpd is controlled to be the high level and the low level alternately.

Additionally, each time a row is selected, the ADC 232 in the first column counts down and up to generate temperature data Dt. On the other hand, each time a row is selected, the ADCs 232 in the second and subsequent columns count down and up to generate pixel data Dv.

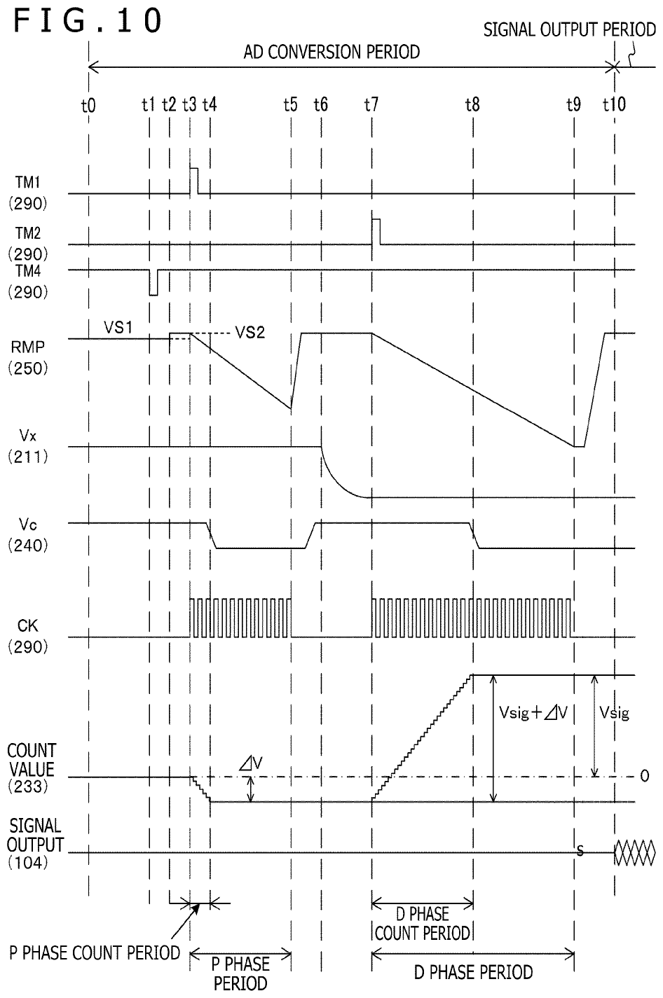

FIG. 10 is a timing chart depicting an example of an AD conversion operation performed on the pixel signal Vx by the image sensor 103 according to the first embodiment of the present technology.

In FIG. 10, an AD conversion period is started, for example, at a time t0 when an exposure period is assumed to have been ended. At the beginning of the AD conversion period, the DAC 250 first outputs a clamp voltage VS1 as the reference signal RMP.

It is assumed that, for example, after the AD conversion period is started at a time t1, the time t1 is reached when the potential obtained at the column signal line 213 and the potential of the signal line for the reference signal RMP may be considered to be stabilized. Then, the timing control circuit 290 causes a pulse of an L level to be output as the timing signal TM4 to achieve a Low active state. In response to the output, input terminal potential reset is performed to make potentials of two input terminals of the comparator 240 substantially identical.

However, in actuality, when the period of time of the input terminal potential reset in the comparator 240 is short or when the offset of the input potential is completely cancelled to make the potentials substantially identical, there is a possibility that a malfunction as described below may occur. Specifically, the output of the comparator 240 that is to be inverted may not be inverted, or the output of the comparator 240 that is not to be inverted may be inverted. Thus, in the embodiment of the present invention, a configuration as described below may be adopted. Specifically, for example, at a time t2 after a certain period of time has elapsed since the time t1 that is an execution timing of the input potential reset, the voltage level of the reference signal RMP is changed from the clamp voltage VS1 to an initial voltage VS2. In this way, it is possible to prevent the above-described malfunction in the comparator 240.

In this regard, before a time t6, the pixel 211 to be read is assumed to be in the state of a reset operation, and a potential that is a reset component obtained by the FD section appears on the column signal line 213. Thus, before the time t6, the comparator 240 compares the voltage value of the pixel signal Vx for the reset components with the voltage value of the reference signal RMP and outputs an output signal Vc.

The initial voltage value VS2 as the reference signal RMP is higher than the voltage value of the reset components obtained as the pixel signal Vx. On the basis of this, before a time t3, the output signal Vc from the comparator 240 is in the state of outputting an H level.

Then, a period of time from the time t3 to a time t5 is set to the P phase period. The P phase period has a predetermined time length defined in advance. During the P phase period, the timing control circuit 290 generates and outputs, as the reference signal RMP, a ramp waveform that is attenuated at a fixed predetermined gradient with the lapse of time. Additionally, at the time t3 that is a timing of starting the P phase period, for example, a pulse of the H level (P phase count start pulse) is output as the timing signal TM1. In response to the P phase count start pulse, the counter 233 starts counting down. In other words, as depicted in FIG. 10, at the time t3, the counter 233 starts, for example, a count-down operation with a count value of 0 by using a count timing that synchronizes with a clock signal CK. Note that, although not depicted herein, the count value of the counter 233 is reset to 0 at a predetermined timing before the time t3.

In FIG. 10, it is assumed that, at a time t4, the pixel signal Vx input to the comparator 240 and the reference signal RMP with the ramp waveform are changed such that the reference signal RMP has a lower voltage value than that of the pixel signal Vx. In response to the change, the output signal Vc from the comparator 240 is inverted from the H level to the L level at the time t4. Additionally, the counter 233 is configured to stop the count-down operation at the timing when the output signal Vc that is received as input is inverted. Thus, the counter 233 stops, at the time t4, the count-down operation started at the time t3. Consequently, in this case, a period of time from the time t3 to the time t4 corresponds to a P phase count period when the count-down operation is actually performed during the P phase period. Additionally, the counter 233 includes a latch function to hold the last count value obtained by the count-down operation, at the time t4 and later, in response to the stoppage of the count-down operation.

After the time t4, when the P phase count period is ended at the time t5, the DAC 250 restores, to the initial voltage value VS2, the value of the reference signal RMP that has been attenuated with the ramp waveform, for example. As a result, at a certain timing after the time t5, the reference signal RMP has a higher voltage value than that of the pixel signal Vx, and thus, the output signal Vc from the comparator 240 is inverted and changed to the H level.

Additionally, at the time t6 after a predetermined period of time has elapsed since the end of the P phase count period, on the pixel 211 side, the reset operation having been performed transitions to a transfer operation. Thus, a voltage value of light receiving signal components appears on the column signal line 213, the voltage value corresponding to charges accumulated in the photodiode according to the amount of received light.

Then, at a time t7, a D phase period from the time t7 to a time t9 is set. During the D phase period, the DAC 250 starts outputting the reference signal RMP with the ramp waveform again. Additionally, at the time t7, for example, a pulse of the H level (D phase count start pulse) is output as the timing signal TM2. In response to the output, the counter 233 starts counting up. The counter 233 starts counting up from the count value held at the time of the count-down operation during the last P phase count period (t3 to t4).

At the time t7 that is a start point for the D phase count period, the reference signal RMP has a higher voltage value than that of the pixel signal Vx, and thus, the output signal Vc from the comparator 240 maintains to be at the H level. However, the reference signal RMP has a ramp waveform. In this case, it is thus assumed that the reference signal RMP has a lower voltage value than that of the pixel signal Vx at a time t8 after a certain period of time has elapsed since the time t7. Accordingly, at the time t8, the output signal Vc from the comparator 240 is inverted to the L level.

In response to the inversion of the output signal Vc from the comparator 240 at the time t8, the counter 233 stops counting up and holds, after the time t8, the count value obtained at the point of time when the count-up operation is stopped.

Here, the absolute value of a negative count value obtained during the P phase count period (t3 to t4) indicates a level (voltage value) corresponding to reset components ΔV. Additionally, a positive count value obtained by the count-up operation during the D phase count period (t7 to t8) indicates a level (voltage value) corresponding to signal components Vsig based on the amount of received light. Note that, during the D phase count period, the counter 233 starts counting up from the count value that is obtained during the P phase count period and that corresponds to the reset components ΔV.

Consequently, the count-down operation during the P phase count period and the count-up operation during the D phase count period that are performed by the counter 233 are equivalent to execution of a calculation expressed by the following equation.

(Vsig+ΔV)−ΔV=Vsig Equation 13

Additionally, in actuality, the reset components ΔV and the signal components Vsig include offset components ΔVofs of the corresponding ADC 232. Consequently, Equation 13 can be transformed as follows.

(Vsig+ΔV+ΔVofs)−(ΔV+ΔVofs)=Vsig Equation 14

For example, the reset components ΔV include variation components corresponding to a variation in each pixel 211. Consequently, Equation 14 means that obtained is an accurate value in which variation components of the voltage value attributable to a variation in each pixel 211 and offset components of the ADC 232 have been cancelled.

In such a manner as described above, in the imaging mode, the ADC 232 of the column ADC 230 executes CDS processing when converting the pixel signal Vx in an analog form into a digital signal. This allows a more faithful signal value to be obtained.

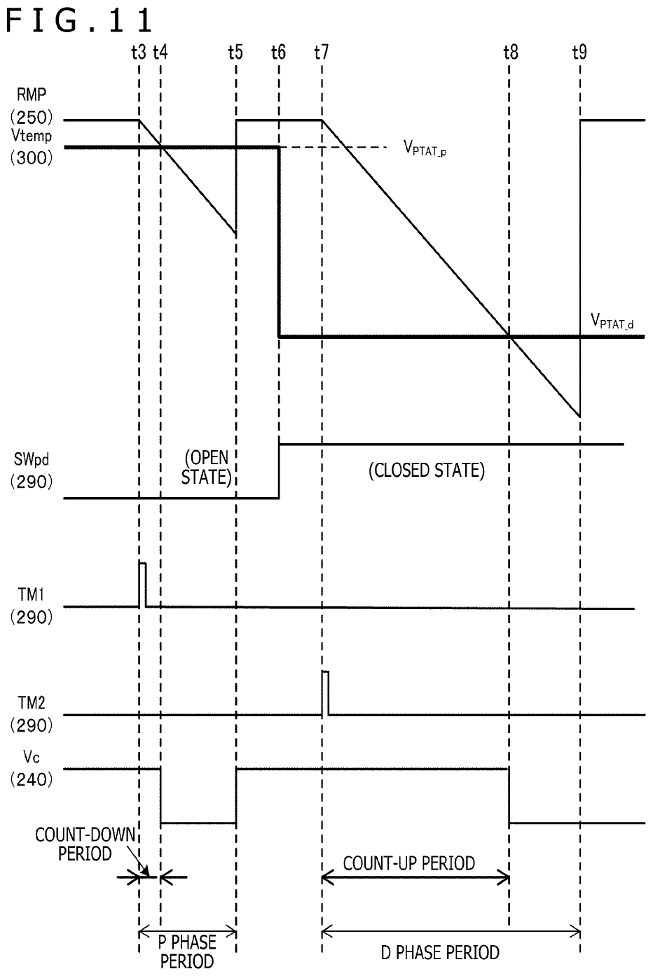

FIG. 11 is a timing chart depicting an example of an AD conversion operation performed on the temperature signal Vtemp by the image sensor 103 according to the first embodiment of the present technology. Note that times t3, t4, t5, t6, t7, and t9 in FIG. 11 correspond to the times t3, t4, t5, t6, t7, and t9 in FIG. 10, respectively.

FIG. 11 depicts operations performed at the time t3 and later. The time t3 is a timing of starting the P phase period, and the reference signal RMP starts being attenuated from the initial voltage value VS2 at a constant gradient.

Additionally, at the time t3, a P phase count start pulse rises as the timing signal TM1. In response to the rise, the counter 233 corresponding to the temperature signal Vtemp starts counting down from a count value of 0. Note that, here, a count value obtained when the counter 233 starts counting down from a count of 0 is assumed to be a negative value.

When the count-down operation is performed, the timing control circuit 290 uses the control signal SWpd to set the switch 316 to the open state. The voltage value of the voltage V_{PTAT_p} at this time is expressed by Equation 7.

At the time t3 and later, the voltage value of the reference signal RMP decreases with the ramp waveform. For example, at the time t4 after a certain period of time has elapsed since the time t3, the state of the reference signal RMP changes such that the voltage V_{PTAT_p} is higher than the voltage of the reference signal RMP. As a result, the output signal Vc from the comparator 240 is inverted from the H level to the L level, and the counter 233 stops the count operation and holds the count value obtained thus far by the count-down operation.

The P phase period is ended at the time t5. At the time t5, the voltage value of the reference signal RMP returns to, for example, the initial voltage value VS2. As a result, the output signal Vc from the comparator 240 is inverted to the H level.

Then, at the time t6 that is a predetermined time before the time t7 when the D phase period is started, the timing control circuit 290 uses the control signal SWpd to set the switch 316 to the closed state. The voltage value of the voltage V_{PTAT_d} at this time is expressed by Equation 11.

Then, at the time t7, the D phase period is started. At the time t7 that is a timing of starting the D phase period, the reference signal RMP starts decreasing again at a constant gradient. Additionally, at the time t7, a D phase count start pulse rises as a timing signal TM2. In response to the rise, the counter 233 corresponding to the temperature signal Vtemp starts counting up.

It is assumed that, in this case, the level of the reference signal RMP is lower than that of the temperature signal Vtemp at the time t8, inverting the output signal Vc from the comparator 240 to the L level. In response to the inversion, the counter 233 stops counting up and holds the count value. Thus, the D phase count period is ended. Then, the counter 233 outputs the count value obtained during the D phase count period, as the temperature data Dt, at a timing when the counter 233 receives a column control signal from the column scanning circuit 260.

Thereafter, if it is assumed that the time t9 when the D phase period is ended is reached, for example, the voltage value of the reference signal RMP returns to the initial voltage value again.

In such a manner, the ADC 232 to which the temperature signal Vtemp has been input AD-converts the input temperature signal Vtemp and outputs the resultant signal as the temperature data Dt. The value of the temperature data Dt is expressed by Equation 12.

Note that the image sensor 103 AD-converts the voltage provided when the switch 316 is in the open state, and then AD-converts the voltage provided when the switch 316 is in the closed state. However, the present technology is not limited to this configuration. In contrast, the image sensor 103 can AD-convert the voltage provided when the switch 316 is in the closed state, and can then AD-convert the voltage provided when the switch 316 is in the open state.

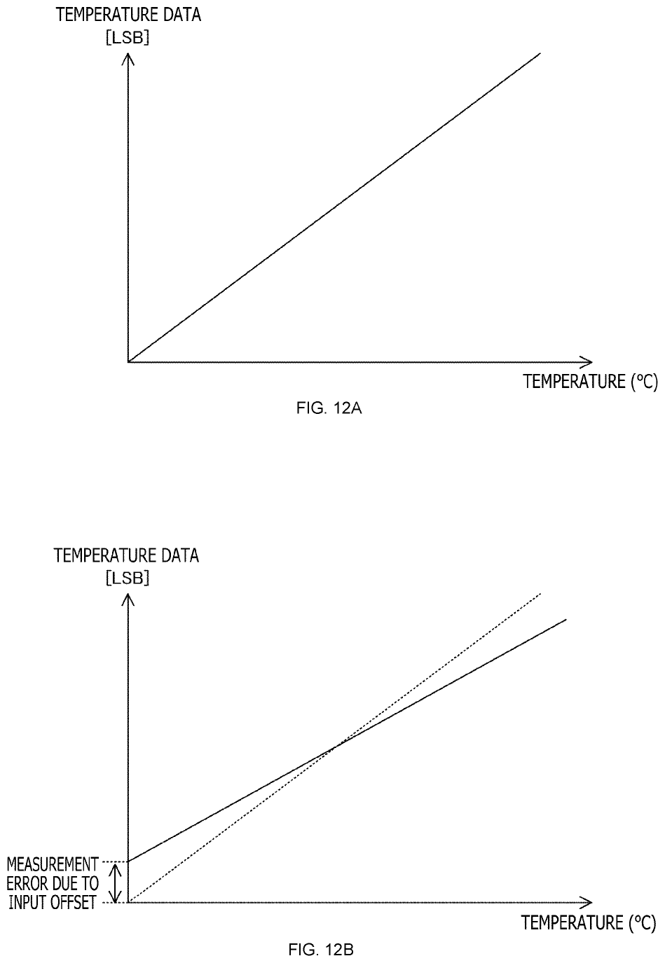

FIG. 12 depicts graphs for describing an example of temperature measurement results in the first embodiment of the present technology and in a comparative example. In FIG. 12, a is a graph depicting an example of temperature measurement results in the first embodiment of the present technology. In FIG. 12, b is a graph depicting an example of temperature measurement results in the comparative example in which the bipolar transistor 315 and the switch 316 are not provided. Additionally, in FIG. 12, a vertical axis indicates temperature data in units of LSBs (Least Significant Bits), and a horizontal axis indicates temperature. In addition, in b of FIG. 12, a solid line indicates temperature characteristics that are actually measured, and a dotted line indicates ideal temperature characteristics with no errors.

As illustrated in a of FIG. 12, temperature data acquired on the basis of a difference has a value proportional to temperature. Additionally, as illustrated in b of FIG. 12, a measurement error caused by the input offset voltage occurs in temperature data in the comparative example in which no difference is acquired. The measurement error is minimized at a predetermined temperature, but a larger measurement error arises with an increase or a decrease in temperature from the predetermined temperature.

By providing the bipolar transistor 315 and the switch 316 and acquiring the difference, components of the input offset voltage can be removed as illustrated in Equation 12. Thus, as illustrated in a of FIG. 12, measurement errors caused by the input offset voltage can be suppressed.

### [Operation Example of Imaging Apparatus]

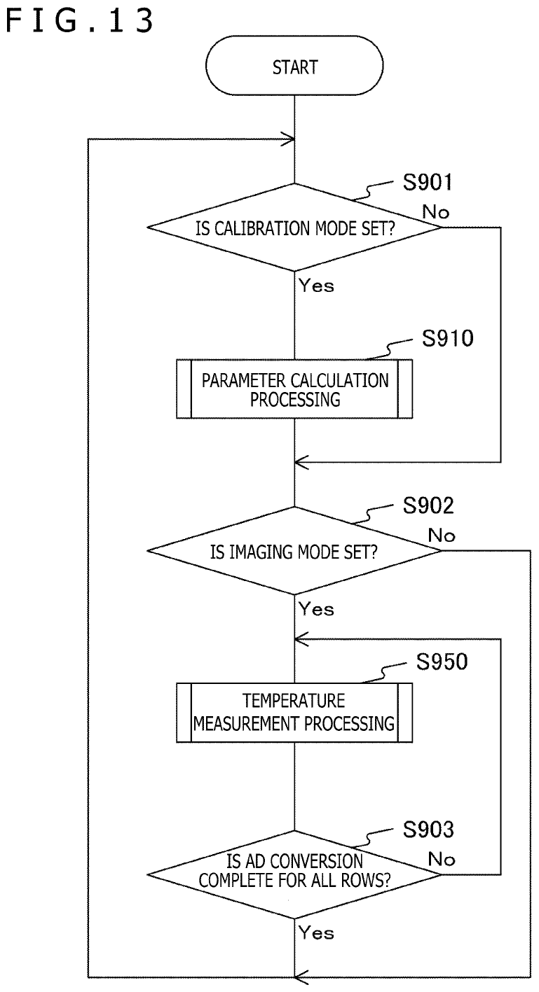

FIG. 13 is a flowchart depicting an example of operations of the imaging apparatus 100 according to the first embodiment of the present technology. The operations are initiated when the imaging apparatus 100 is powered on.

The imaging apparatus 100 determines whether or not the calibration mode is set (step S901). In a case where the calibration mode is set (step S901: Yes), the imaging apparatus 100 executes parameter calculation processing for calculating temperature calculation parameters (step S910).

In a case where the calibration mode is not set (step S901: No) or after step S910, the imaging apparatus 100 determines whether or not the imaging mode is set (step S902). In a case where the imaging mode is set (step S902: Yes), the imaging apparatus 100 executes temperature measurement processing for measuring temperature while AD-converting the pixel signal for each row (step S950).

In a case where the imaging mode is not set (step S902: No) or after step S950, the imaging apparatus 100 determines whether or not the AD conversion is complete for all the rows (step S903). In a case where the AD conversion is not complete for all the rows (step S903: No), the image sensor 103 repeats step S950 and the subsequent steps. On the other hand, in a case where the AD conversion is complete for all the rows (step S903: Yes), the imaging apparatus 100 repetitively executes step S901 and the subsequent steps.

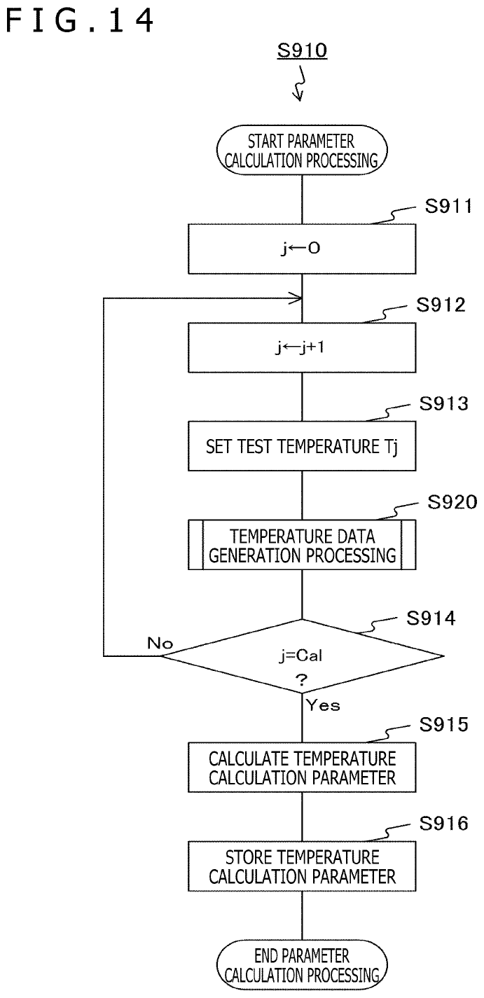

FIG. 14 is a flowchart depicting an example of the parameter calculation processing according to the first embodiment of the present technology. The signal processing section 104 in the imaging apparatus 100 initializes a variable j (j is an integer) indicating the number of measurements to “0” (step S911), and increments the variable j (step S912).

The signal processing section 104 sets the j-th test temperature Tj (step S913), and the image sensor 103 in the imaging apparatus 100 executes temperature data generation processing for generating temperature data Dt (step S920). Then, the signal processing section 104 determines whether or not the variable j (that is, the number of measurements) has reached a predetermined number Cal (step S914). In a case where the number of measurements is less than Cal (step S914: No), the signal processing section 104 repeats step S912 and the subsequent steps.

On the other hand, in a case where the number of measurements reaches Cal (step S914: Yes), the signal processing section 104 calculates temperature calculation parameters on the basis of the measurement value (step S915), and stores the temperature calculation parameters in the parameter storage section 430 (step S916). After step S916, the imaging apparatus 100 ends the parameter calculation processing.

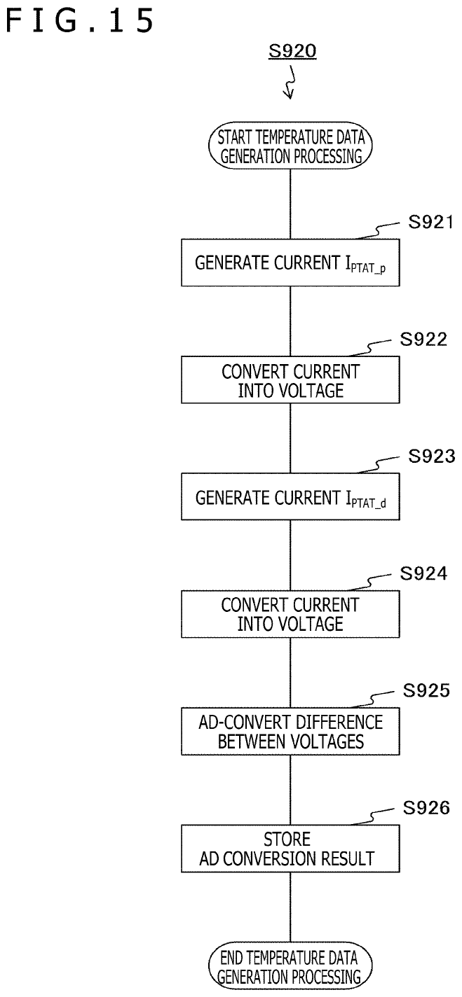

FIG. 15 is a flowchart depicting an example of the temperature data generation processing according to the first embodiment of the present technology. The temperature signal output circuit 300 in the image sensor 103 generates a current I_{PTAT_p} provided when the switch 316 is in the open state (step S921) and converts the current I_{PTAT_p} into a voltage V_{PTAT_p} (step S922). Then, the temperature signal output circuit 300 generates a current I_{PTAT_d} provided when the switch 316 is in the closed state (step S923) and converts the current I_{PTAT_d} into a voltage V_{PTAT_d} (step S924). The ADC 232 AD-coverts the difference between those voltages (step S925) and stores an AD conversion result in the memory or the like as the temperature data Dt (step S926). After step S926, the image sensor 103 ends the temperature data generation processing.

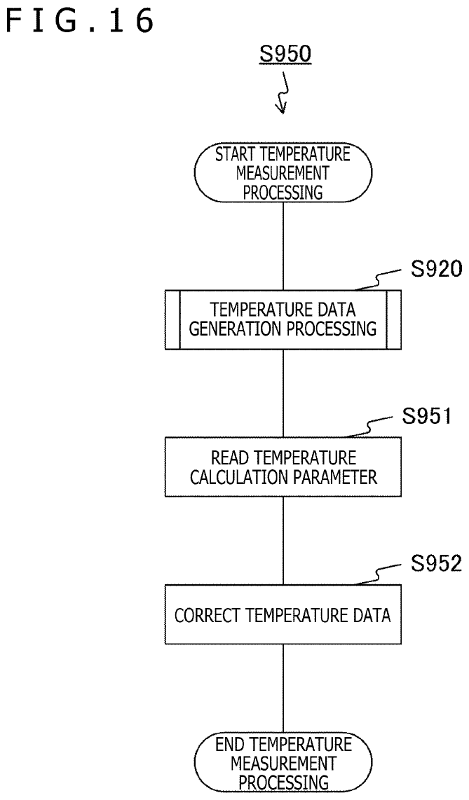

FIG. 16 is a flowchart depicting an example of the temperature measurement processing according to the first embodiment of the present technology. The image sensor 103 executes the above-described temperature data generation processing (step S920), and the signal processing section 104 reads the temperature calculation parameters from the parameter storage section 430 (step S951). Then, the signal processing section 104 uses temperature correction parameters to correct temperature data and outputs the resultant data (step S952). After step S952, the imaging apparatus 100 ends the temperature measurement processing.

In such a manner as described above, according to the first embodiment of the present technology, the difference between the voltage obtained before connection of the bipolar transistor 315 and the voltage obtained after connection of the bipolar transistor 315 is acquired as temperature data, allowing components of the input offset voltage of the operational amplifier 311 to be removed. This configuration allows the temperature measurement accuracy to be improved compared to a configuration in which no difference is acquired.

### 2. Second Embodiment

In the above-described first embodiment, the temperature signal output circuit 300 outputs the current I_{PTAT} via the current mirror circuit (nMOS transistors 334 and 335). However, the provision of the current mirror circuit increases the circuit scale of the image sensor 103. The temperature signal output circuit 300 of the second embodiment differs from the temperature signal output circuit 300 of the first embodiment in that the current mirror circuit is omitted from the temperature signal output circuit 300 of the second embodiment.

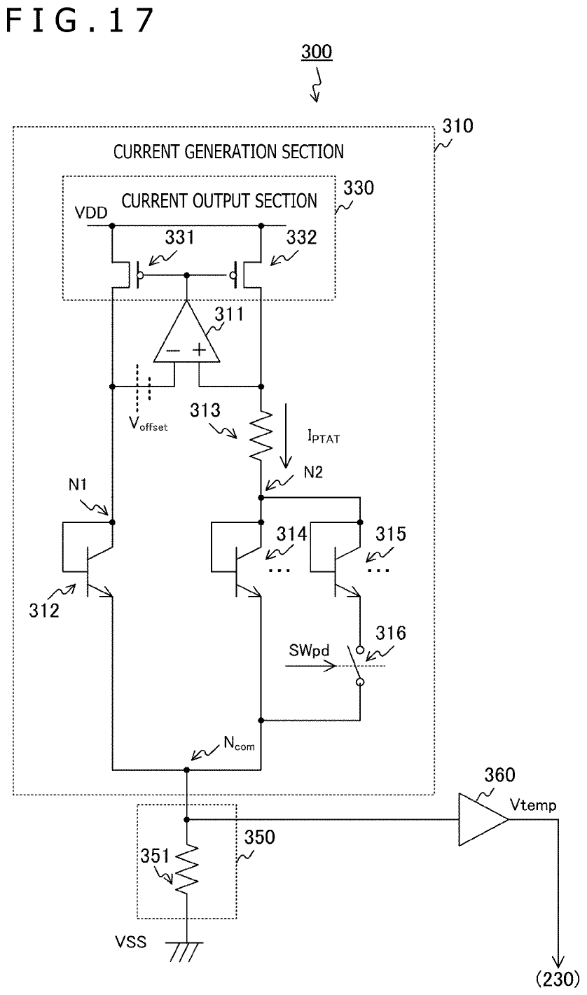

FIG. 17 is a circuit diagram depicting a configuration example of the temperature signal output circuit 300 according to the second embodiment of the present technology. The temperature signal output circuit 300 of the second embodiment differs from the temperature signal output circuit 300 of the first embodiment in that the pMOS transistor 333 and the nMOS transistors 334 and 335 are not disposed in the current output section 330 of the temperature signal output circuit 300 of the second embodiment. Additionally, the current-to-voltage conversion section 350 is interposed between the common node N_{com} and the ground potential VSS. As illustrated in FIG. 17, the current-to-voltage conversion section 350 disposed between the common node N_{com} and the ground potential VSS eliminates the need for the current mirror circuit. Additionally, the current I_{PTAT} on the positive side and the current I_{PTAT} on the negative side join together at the common node Ncom, and thus, the value of the output voltage is double the value obtained in the first embodiment.

In such a manner as described above, according to the second embodiment of the present technology, the current-to-voltage conversion section 350 is disposed between the common node N_{com} and the ground potential VSS, allowing the current mirror circuit to be omitted.

### 3. Third Embodiment

In the above-described first embodiment, the current-to-voltage conversion section 350 converts a current into a voltage. However, the provision of the current-to-voltage conversion section 350 increases the circuit scale of the image sensor 103. The temperature signal output circuit 300 of the second embodiment differs from the temperature signal output circuit 300 of the first embodiment in that the current-to-voltage conversion section is omitted from the temperature signal output circuit 300 of the second embodiment.

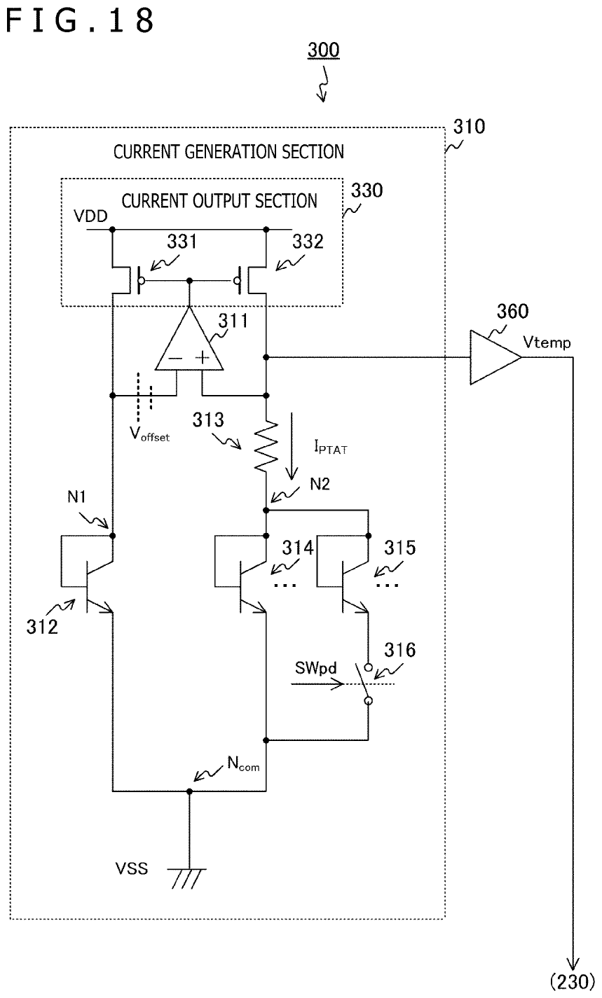

FIG. 18 is a circuit diagram depicting a configuration example of the temperature signal output circuit 300 according to a third embodiment of the present technology. The temperature signal output circuit 300 of the third embodiment differs from the temperature signal output circuit 300 of the first embodiment in that the pMOS transistor 333 and the nMOS transistors 334 and 335 are not disposed in the current output section 330 of the temperature signal output circuit 300 of the third embodiment. A node between the pMOS transistor 332 and the resistor 313 is connected to the voltage buffer 360. This connection configuration allows the resistor 313 to convert a current I_{PTAT} into a voltage V_{PTAT}, and a signal for the converted voltage is output by the voltage buffer 360. The resistor 313 converts a current into a voltage, thereby eliminating the need for the current-to-voltage conversion section 350.

In such a manner as described above, according to the third embodiment of the present technology, the resistor 313 converts a current into a voltage, thereby allowing the current-to-voltage conversion section 350 to be omitted.

### 4. Fourth Embodiment

In the above-described first embodiment, the temperature signal output circuit 300 outputs the current I_{PTAT} via the current mirror circuit (nMOS transistors 334 and 335). However, the provision of the current mirror circuit increases the circuit scale of the image sensor 103. The temperature signal output circuit 300 of the fourth embodiment differs from the temperature signal output circuit 300 of the first embodiment in that the current mirror circuit is omitted from the temperature signal output circuit 300 of the fourth embodiment.

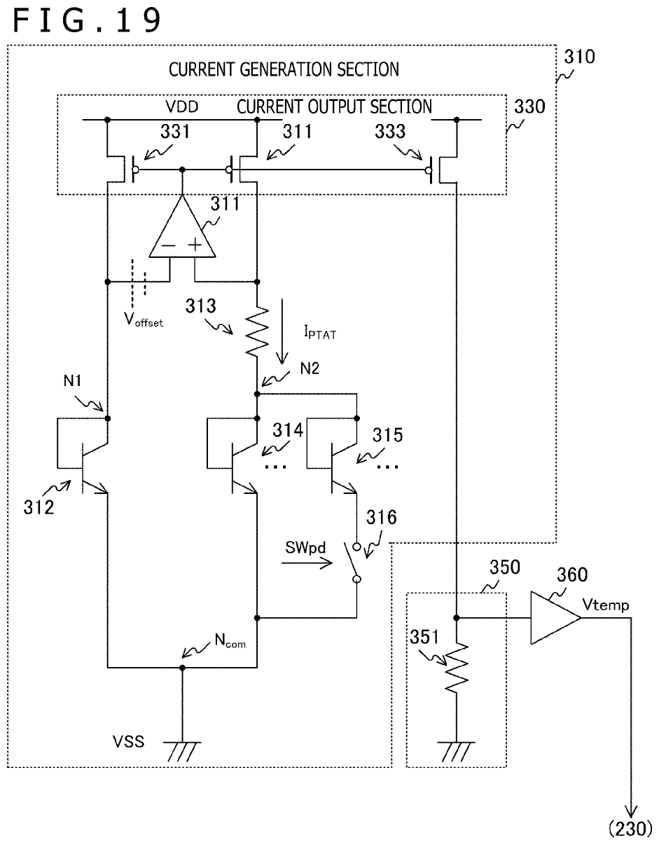

FIG. 19 is a circuit diagram depicting a configuration example of the temperature signal output circuit 300 according to the fourth embodiment of the present technology. The temperature signal output circuit 300 of the fourth embodiment differs from the temperature signal output circuit 300 of the first embodiment in that the nMOS transistors 334 and 335 are not disposed in the temperature signal output circuit 300 of the fourth embodiment. Additionally, the current-to-voltage conversion section 350 is disposed between the pMOS transistor 333 and the ground potential VSS. As illustrated in FIG. 19, the current-to-voltage conversion section 350 is disposed on the ground potential VSS side, thereby eliminating the need for the current mirror circuit.

According to the fourth embodiment of the present technology, the current-to-voltage conversion section 350 is disposed between the pMOS transistor 333 and the ground potential VSS, thereby allowing the current mirror circuit to be omitted.

### 5. Fifth Embodiment

In the above-described first embodiment, the bipolar transistor 315 is connected in parallel with bipolar transistors on the positive side. However, a bipolar transistor can further be connected in parallel with bipolar transistors on the negative side. The temperature signal output circuit 300 of the fifth embodiment differs from the temperature signal output circuit 300 of the first embodiment in that a bipolar transistor is connected in parallel with bipolar transistors on the negative side in the temperature signal output circuit 300 of the fifth embodiment.

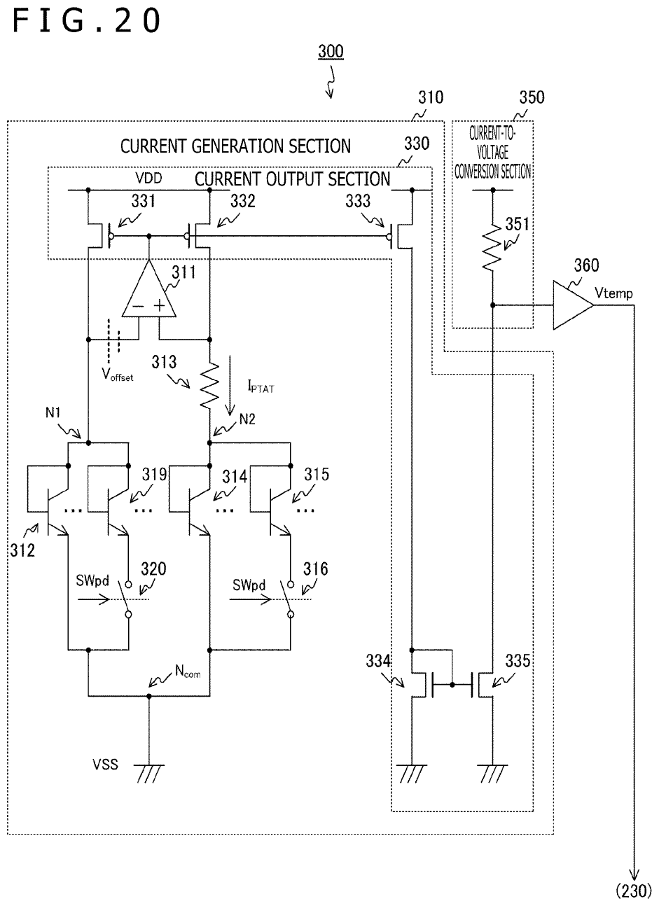

FIG. 20 is a circuit diagram depicting a configuration example of the temperature signal output circuit 300 according to the fifth embodiment of the present technology. The temperature signal output circuit 300 of the fifth embodiment differs from the temperature signal output circuit 300 of the first embodiment in that the temperature signal output circuit 300 of the fifth embodiment is further provided with a bipolar transistor 319 and a switch 320.

The switch 320 connects the bipolar transistor 319 in parallel with the bipolar transistor 312 on the negative side according to the control signal SWpd. Any number of bipolar transistors 319 are provided, and the number of bipolar transistors 319 is denoted by J (J is an integer). Note that the bipolar transistors 312 and 319 are examples of first and second additional rectification elements recited in the claims, and the switches 316 and 320 are examples of first and second switches recited in the claims.

The voltage V_{PTAT_p} provided when the switches 316 and 320 are in the open state is similar to the voltage V_{PTAT_p} in the first embodiment. On the other hand, the voltage V_{PTAT_d} provided when the switches 316 and 320 are in the closed state is expressed by the following equation.

$${V}_{PTAT\_d} = R \cdot {I}_{PTAT\_d} = {V}_{offset} + ( kT / q ) \cdot ln \{ ( K + L ) / J \} \qquad Equation 15$$

The temperature data Dt is calculated by substituting, into Equation 12, the value of Equation 15 instead of Equation 11. Connection of J bipolar transistors 319 allows the value of J to be set in addition to the values of K and L, facilitating fine-tuning of the coefficient of the temperature.

Note that the second to fourth embodiments can also be applied to the fifth embodiment.

In such a manner as described above, according to the fifth embodiment of the present technology, the switch 320 connects the bipolar transistor 319 in parallel with the bipolar transistor 312, thereby allowing the coefficients to be easily fine-tuned.

### 6. Sixth Embodiment

In the above-described first embodiment, the diode-connected bipolar transistors 312, 314, and 315 are disposed in the temperature signal output circuit 300 as rectification elements. However, instead of the transistors, diodes can be disposed. The temperature signal output circuit 300 of the sixth embodiment differs from the temperature signal output circuit 300 of the first embodiment in that the temperature signal output circuit 300 of the sixth embodiment includes diodes used as rectification elements.

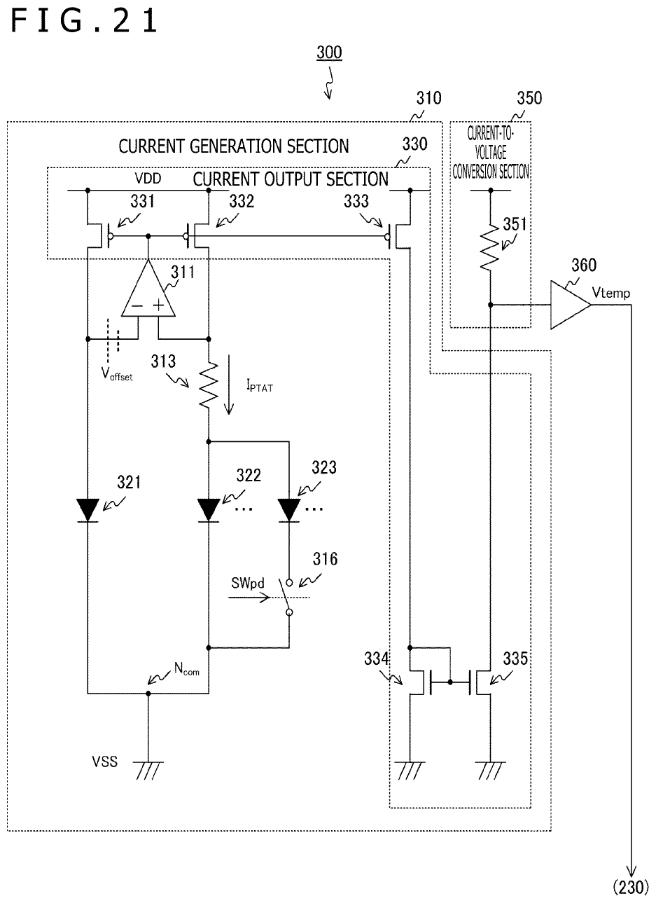

FIG. 21 is a circuit diagram depicting a configuration example of the temperature signal output circuit 300 according to the sixth embodiment of the present technology. The temperature signal output circuit 300 of the sixth embodiment differs from the temperature signal output circuit 300 of the first embodiment in that, instead of the bipolar transistors 312, 314, and 315, diodes 321, 322, and 323 are disposed in the temperature signal output circuit 300 of the sixth embodiment. The temperature characteristics of the diodes are used to generate temperature data Dt as is the case with the first embodiment.

Note that the second to fifth embodiments can also be applied to the sixth embodiment.

In such a manner as described above, according to the sixth embodiment of the present technology, the diodes 321, 322, and 323 are disposed as rectification elements, thereby allowing temperature data Dt to be generated using the temperature characteristics of the diodes.

### 7. Example of Application to Mobile Body

The technology according to the present disclosure (present technology) can be applied to various products. For example, the technology according to the present disclosure may be implemented as an apparatus mounted in any type of a mobile body such as an automobile, an electric vehicle, a hybrid electric vehicle, a motorcycle, a bicycle, a personal transporter, an airplane, a drone, a ship, or a robot.

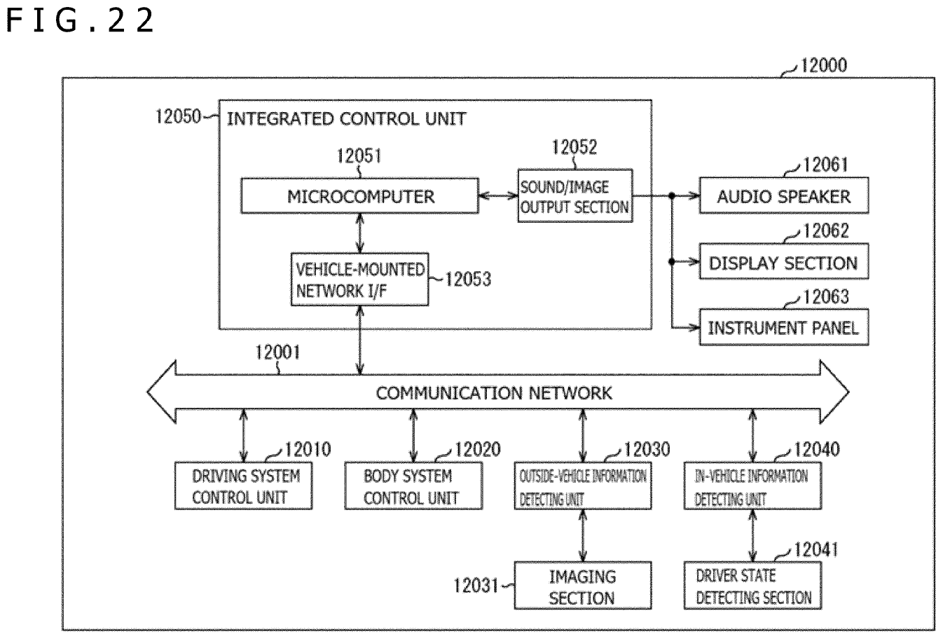

FIG. 22 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 22, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 22, an audio speaker 12061, a display section 12062, and an instrument panel 12063 are illustrated as the output device. The display section 12062 may, for example, include at least one of an on-board display and a head-up display.

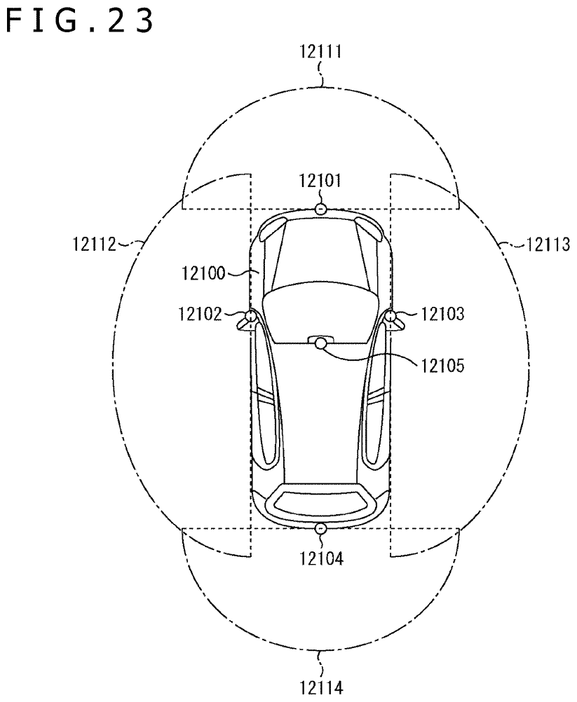

FIG. 23 is a diagram depicting an example of the installation position of the imaging section 12031.

In FIG. 23, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 23 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to XX (a block to which the present invention is applied. For example, the imaging section 12031 or the like) included in the above-described configuration. For example, the image sensor 103 in FIG. 2 can be applied to the imaging section 12031. By applying the technology according to the present disclosure to the imaging section 12031, correction based on an accurate temperature is performed, and captured images that are more easy-to-see can thus be obtained. Accordingly, it is possible to reduce driver fatigue.

Note that the above-described embodiments are examples for embodying the present technology and that there is a one-to-one correspondence between matters in the embodiments and invention specifying matters in the claims. Similarly, there is a one-to-one correspondence between the invention specifying matters in the claims and those matters in the embodiments of the present technology which have names identical to the names of the invention specifying matters. However, the present technology is not limited to the embodiments and can be embodied by applying various modifications to the embodiments without departing from the spirits of the present technology.

Note that effects described herein are only illustrative and are not restrictive and that other effects may be produced.

Note that the present technology can also take configurations described below.

(1) A measurement circuit including:
an operational amplifier configured to output an output voltage corresponding to a difference between terminal voltages of a pair of input terminals;
a resistor having one end connected to one of the pair of input terminals;
a resistor-side rectification element connected to another end of the resistor;
a terminal-side rectification element connected to another one of the pair of input terminals;
an additional rectification element;
a switch configured to connect the additional rectification element in parallel with either the resistor-side rectification element or the terminal-side rectification element;
a current output section configured to output a current corresponding to the output voltage; and
a difference acquisition section configured to acquire, as temperature data, a difference between a signal corresponding to the current provided when the additional rectification element is not connected to the resistor-side rectification element or the terminal-side rectification element and a signal corresponding to the current provided when the additional rectification element is connected to the resistor-side rectification element or the terminal-side rectification element.

(2) The measurement circuit according to (1) described above, further including:
a current-to-voltage conversion section configured to convert the current into a voltage, in which
the difference acquisition section acquires a difference in the voltage as the temperature data.

(3) The measurement circuit according to (2) described above, in which
the current output section includes
   a current mirror circuit configured to output, to the current-to-voltage conversion section, a current supplied from an input node,
   a first P-type transistor that is interposed between a power supply and the terminal-side rectification element and that has a gate to which the output voltage is input,
   a second P-type transistor that is interposed between the power supply and the resistor and that has a gate to which the output voltage is input, and
   a third P-type transistor that is interposed between the power supply and the input node and that has a gate to which the output voltage is input.

(4) The measurement circuit according to (2) described above, in which
the current output section includes
   a first P-type transistor that is interposed between a power supply and the terminal-side rectification element and that has a gate to which the output voltage is input, and
   a second P-type transistor that is interposed between the power supply and the resistor and that has a gate to which the output voltage is input, and
the terminal-side rectification element and the resistor-side rectification element are connected to the current-to-voltage conversion section via a common node and share a common connection.

(5) The measurement circuit according to (2) described above, in which
the current generation section includes
   a first P-type transistor that is interposed between a power supply and the terminal-side rectification element and that has a gate to which the output voltage is input,
   a second P-type transistor that is interposed between the power supply and the resistor and that has a gate to which the output voltage is input, and
   a third P-type transistor that is interposed between the power supply and the current-to-voltage conversion section and that has a gate to which the output voltage is input.

(6) The measurement circuit according to (1) described above, further including:
a voltage buffer configured to output a voltage of a node between the resistor and the current output section.

(7) The measurement circuit according to any one of (1) to (6) described above, in which
the additional rectification element includes a first additional rectification element and a second additional rectification element,
the switch includes a first switch and a second switch,
the first switch connects the first additional rectification element in parallel with one of the resistor-side rectification element and the terminal-side rectification element, and
the second switch connects the second additional rectification element in parallel with another one of the resistor-side rectification element and the terminal-side rectification element.

(8) The measurement circuit according to any one of (1) to (7) described above, in which
the terminal-side rectification element, the resistor-side rectification element, and the additional rectification element are diode-connected transistors.

(9) The measurement circuit according to any one of (1) to (7) described above, in which
the terminal-side rectification element, the resistor-side rectification element, and the additional rectification element are diodes.

(10) The measurement circuit according to any one of (1) to (9) described above, further including:
a dummy switch that is in an on-state and that is disposed at each position between the resistor-side rectification element and a predetermined common node and between the terminal-side rectification element and the predetermined common node, in which
the switch and the dummy switch include transistors having an identical polarity.

(11) Electronic equipment including:
an operational amplifier configured to output an output voltage corresponding to a difference between terminal voltages of a pair of input terminals;
a resistor having one end connected to one of the pair of input terminals;
a resistor-side rectification element connected to another end of the resistor;
a terminal-side rectification element connected to another one of the pair of input terminals;
an additional rectification element;
a switch configured to connect the additional rectification element in parallel with either the resistor-side rectification element or the terminal-side rectification element;
a current output section configured to output a current corresponding to the output voltage;
a difference acquisition section configured to acquire, as temperature data, a difference between a signal corresponding to the current provided when the additional rectification element is not connected to the resistor-side rectification element or the terminal-side rectification element and a signal corresponding to the current provided when the additional rectification element is connected to the resistor-side rectification element or the terminal-side rectification element; and
a signal processing section configured to process a pixel signal on the basis of the temperature data.

(12) The electronic equipment according to (11) described above, in which
the signal processing section includes
   a parameter calculation section configured to calculate a parameter for correcting the temperature data on the basis of the temperature data and a predetermined set temperature,
   a parameter storage section configured to store the parameter, and
   a temperature characteristic correction section configured to correct the temperature data by using the stored parameter.

(13) The electronic equipment according to (11) or (12) described above, further including:
a pixel configured to generate the pixel signal; and
a selector configured to select either the pixel signal or a temperature signal corresponding to the current and output the selected signal to the difference acquisition section, in which
the difference acquisition section converts the temperature signal into a digital signal and acquires the difference in a case where the temperature signal is selected, and the difference acquisition section converts the pixel signal into a digital signal in a case where the pixel signal is selected.

### REFERENCE SIGNS LIST

100: Imaging apparatus
101: Optical system section
102: Filter
103: Image sensor
104: Signal processing section
105: Encoding/decoding section
106: Medium drive
107: Recording medium
108: Control section
109: Gain setting section
110: Shutter driving section
111: Diaphragm driving section
112: Display section
113: Operation section
114: Illuminance detection section
121: Lens section
122: Diaphragm
210: Pixel array
211: Pixel
220: Row investigation circuit
230: Column ADC
231: Selector
232: ADC
233: Counter
240: Comparator
241 to 244, 331 to 333: pMOS transistor
245 to 257, 334, 335: nMOS transistor
248, 249: Capacitor
250: DAC
260: Column scanning circuit
280: Buffer amplifier
290: Timing control circuit
300: Temperature signal output circuit
310: Current generation section
311: Operational amplifier
312, 314, 315, 319: Bipolar transistor
313, 351: Resistor
316, 320: Switch
317, 318: Dummy switch
321, 322, 323: Diode
330: Current output section
350: Current-to-voltage conversion section
360: Voltage buffer
410: Image processing section
420: Parameter calculation section
430: Parameter storage section
440: Temperature characteristic correction section
500: Measurement circuit
12031: Imaging section

1. A measurement circuit comprising:
an operational amplifier configured to output an output voltage corresponding to a difference between terminal voltages of a pair of input terminals;
a resistor having one end connected to one of the pair of input terminals;
a resistor-side rectification element connected to another end of the resistor;
a terminal-side rectification element connected to another one of the pair of input terminals;
an additional rectification element;
a switch configured to connect the additional rectification element in parallel with either the resistor-side rectification element or the terminal-side rectification element;
a current output section configured to output a current corresponding to the output voltage; and
a difference acquisition section configured to acquire, as temperature data, a difference between a signal corresponding to the current provided when the additional rectification element is not connected to the resistor-side rectification element or the terminal-side rectification element and a signal corresponding to the current provided when the additional rectification element is connected to the resistor-side rectification element or the terminal-side rectification element.

2. The measurement circuit according to claim 1, further comprising:
a current-to-voltage conversion section configured to convert the current into a voltage, wherein
the difference acquisition section acquires a difference in the voltage as the temperature data.

3. The measurement circuit according to claim 2, wherein
the current output section includes
a current mirror circuit configured to output, to the current-to-voltage conversion section, a current supplied from an input node,
a first P-type transistor that is interposed between a power supply and the terminal-side rectification element and that has a gate to which the output voltage is input,
a second P-type transistor that is interposed between the power supply and the resistor and that has a gate to which the output voltage is input, and
a third P-type transistor that is interposed between the power supply and the input node and that has a gate to which the output voltage is input.

4. The measurement circuit according to claim 2, wherein
the current output section includes
a first P-type transistor that is interposed between a power supply and the terminal-side rectification element and that has a gate to which the output voltage is input, and
a second P-type transistor that is interposed between the power supply and the resistor and that has a gate to which the output voltage is input, and
the terminal-side rectification element and the resistor-side rectification element are connected to the current-to-voltage conversion section via a predetermined common node and share a common connection.

5. The measurement circuit according to claim 2, wherein
the current generation section includes
a first P-type transistor that is interposed between a power supply and the terminal-side rectification element and that has a gate to which the output voltage is input,
a second P-type transistor that is interposed between the power supply and the resistor and that has a gate to which the output voltage is input, and
a third P-type transistor that is interposed between the power supply and the current-to-voltage conversion section and that has a gate to which the output voltage is input.

6. The measurement circuit according to claim 1, further comprising:
a voltage buffer configured to output a voltage of a node between the resistor and the current output section.

7. The measurement circuit according to claim 1, wherein
the additional rectification element includes a first additional rectification element and a second additional rectification element,
the switch includes a first switch and a second switch,
the first switch connects the first additional rectification element in parallel with one of the resistor-side rectification element and the terminal-side rectification element, and
the second switch connects the second additional rectification element in parallel with another one of the resistor-side rectification element and the terminal-side rectification element.

8. The measurement circuit according to claim 1, wherein
the terminal-side rectification element, the resistor-side rectification element, and the additional rectification element are diode-connected transistors.

9. The measurement circuit according to claim 1, wherein
the terminal-side rectification element, the resistor-side rectification element, and the additional rectification element are diodes.

10. The measurement circuit according to claim 1, further comprising:
a dummy switch that is in an on-state and that is disposed at each position between the resistor-side rectification element and a predetermined common node and between the terminal-side rectification element and the predetermined common node, wherein
the switch and the dummy switch include transistors having an identical polarity.

11. Electronic equipment comprising:
an operational amplifier configured to output an output voltage corresponding to a difference between terminal voltages of a pair of input terminals;
a resistor having one end connected to one of the pair of input terminals;
a resistor-side rectification element connected to another end of the resistor;
a terminal-side rectification element connected to another one of the pair of input terminals;
an additional rectification element;
a switch configured to connect the additional rectification element in parallel with either the resistor-side rectification element or the terminal-side rectification element;
a current output section configured to output a current corresponding to the output voltage;
a difference acquisition section configured to acquire, as temperature data, a difference between a signal corresponding to the current provided when the additional rectification element is not connected to the resistor-side rectification element or the terminal-side rectification element and a signal corresponding to the current provided when the additional rectification element is connected to the resistor-side rectification element or the terminal-side rectification element; and
a signal processing section configured to process a pixel signal on a basis of the temperature data.

12. The electronic equipment according to claim 11, wherein
the signal processing section includes
a parameter calculation section configured to calculate a parameter for correcting the temperature data on a basis of the temperature data and a predetermined set temperature,
a parameter storage section configured to store the parameter, and
a temperature characteristic correction section configured to correct the temperature data by using the stored parameter.

13. The electronic equipment according to claim 11, further comprising:
a pixel configured to generate the pixel signal; and
a selector configured to select either the pixel signal or a temperature signal corresponding to the current and output the selected signal to the difference acquisition section, wherein
the difference acquisition section converts the temperature signal into a digital signal and acquires the difference in a case where the temperature signal is selected, and the difference acquisition section converts the pixel signal into a digital signal in a case where the pixel signal is selected.
